(19) United States
(12) Patent Application Publication
(10) Pub. No.: US 2026/0104646 A1
(43) Pub. Date: Apr. 16, 2026

(54) SUBSTRATE PROCESSING METHOD, SUBSTRATE PROCESSING APPARATUS, AND STORAGE MEDIUM

(71) Applicant: Tokyo Electron Limited, Tokyo (JP)

(72) Inventor: Arnaud Alain Jean DAUENDORFFER, Kumamoto (JP)

(73) Assignee: Tokyo Electron Limited, Tokyo (JP)

(21) Appl. No.: 19/344,613

(22) Filed: Sep. 30, 2025

(30) Foreign Application Priority Data
Oct. 10, 2024 (JP) 2024-178330

(51) Int. Cl. G03F 7/36; G03F 7/00

(52) U.S. Cl. CPC G03F 7/36; G03F 7/70875

(57) ABSTRACT

A substrate processing method of forming a pattern by supplying a developing fluid that is gas or mist to a substrate and developing a resist film formed on the substrate and containing metal, the substrate processing method including: a first heat processing step of performing heat processing on the substrate after the resist film is exposed along the pattern, a first developing step of supplying the developing fluid to the substrate on which the first heat processing step is performed and removing a part of the resist film in a depth direction, and a second developing step of supplying the developing fluid to the substrate on which the first developing step is performed for forming the pattern and removing a region from which the resist film is removed in the first developing step in the depth direction to a development completion position.

### CROSS-REFERENCE TO RELATED APPLICATION

This application is based upon and claims the benefit of priority of the prior Japanese Patent Application No. 2024-178330, filed on Oct. 10, 2024, the entire contents of which are incorporated herein by reference.

### FIELD

The present disclosure relates to a substrate processing method, a substrate processing apparatus, and a storage medium.

### BACKGROUND

Manufacturing processing of a semiconductor device includes, for example, photolithography of patterning a resist film by forming the resist film on a substrate such as a semiconductor wafer (hereinafter, referred to as a wafer) and developing after exposing and heating. As the resist film described above, Japanese Laid-open Patent Publication No. JP 2022-538554 describes formation of a resist film containing a tin-based organometallic compound.

### SUMMARY

A substrate processing method of forming a pattern by supplying a developing fluid that is gas or mist to a substrate and developing a resist film formed on the substrate and containing metal, the substrate processing method includes: a first heat processing step of performing heat processing on the substrate after the resist film is exposed along the pattern; a first developing step of supplying the developing fluid to the substrate on which the first heat processing step is performed and removing a part of the resist film in a depth direction; and a second developing step of supplying the developing fluid to the substrate on which the first developing step is performed for forming the pattern and removing a region from which the resist film is removed by the first developing step in the depth direction to a development completion position.

### BRIEF DESCRIPTION OF DRAWINGS

FIG. 1 is a plan view of a wafer processing system according to a first embodiment of the present disclosure;

FIG. 2 is a longitudinal sectional front view of the wafer processing system;

FIG. 3 is a longitudinal sectional side view illustrating a resist film developed in a comparative example;

FIG. 4 is a longitudinal sectional side view illustrating the resist film developed in the comparative example;

FIG. 5 is a longitudinal sectional side view of a developing device provided in the wafer processing system;

FIG. 6 is an explanatory view illustrating a processing step in the developing device;

FIG. 7 is an explanatory view illustrating the processing step in the developing device;

FIG. 8 is an explanatory view illustrating the processing step in the developing device;

FIG. 9 is an explanatory view illustrating the processing step in the developing device;

FIG. 10 is a chart showing changes in a level of development reactivity in the processing step;

FIG. 11 is a chart showing changes in a level of development reactivity in another processing step;

FIG. 12 is a longitudinal sectional side view illustrating the resist film processed by the developing device;

FIG. 13 is a chart showing changes in a level of development reactivity;

FIG. 14 is a chart showing changes in a level of development reactivity;

FIG. 15 is a chart showing changes in a level of development reactivity;

FIG. 16 is a chart showing changes in a level of development reactivity;

FIG. 17 is a longitudinal sectional side view illustrating the resist film processed by the developing device;

FIG. 18 is a chart showing changes in a level of development reactivity;

FIG. 19 is a longitudinal sectional side view illustrating a configuration example of the developing device that supplies developing mist;

FIG. 20 is a longitudinal sectional side view illustrating another configuration example of the developing device that supplies the developing mist;

FIG. 21 is a longitudinal sectional side view illustrating still another configuration example of the developing device that supplies developing gas;

FIG. 22 is a flowchart of processing performed by the developing device; and

FIG. 23 is a flowchart of the processing performed by the developing device.

### DESCRIPTION OF EMBODIMENTS

### First Embodiment

Hereinafter, a wafer processing system as a substrate processing apparatus according to the present embodiment is described with reference to the drawings. Note that, in the present specification, components having substantially the same functional configuration are denoted by the same reference numerals, and redundant description thereof is omitted.

### Wafer Processing System

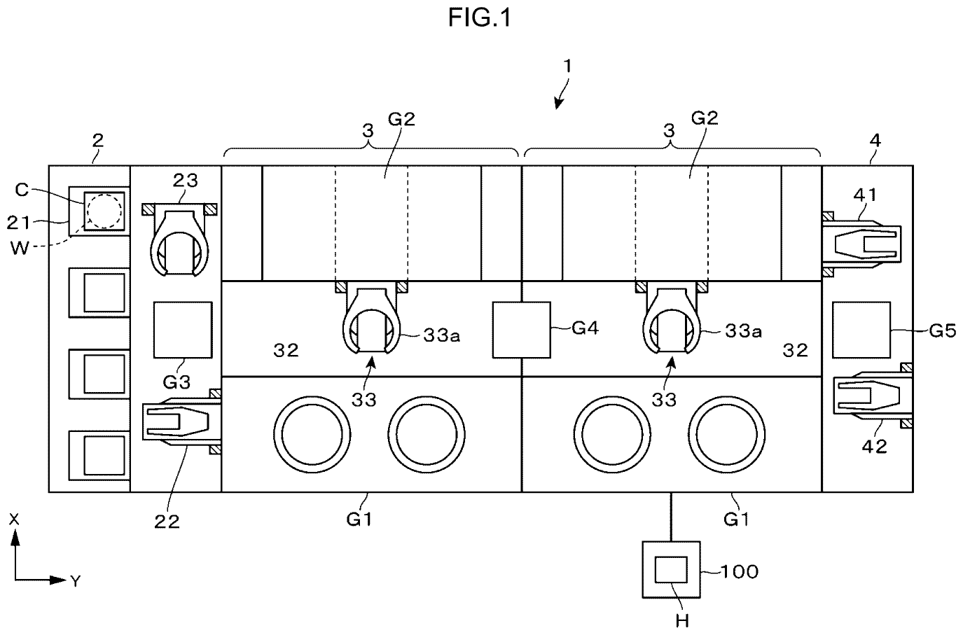

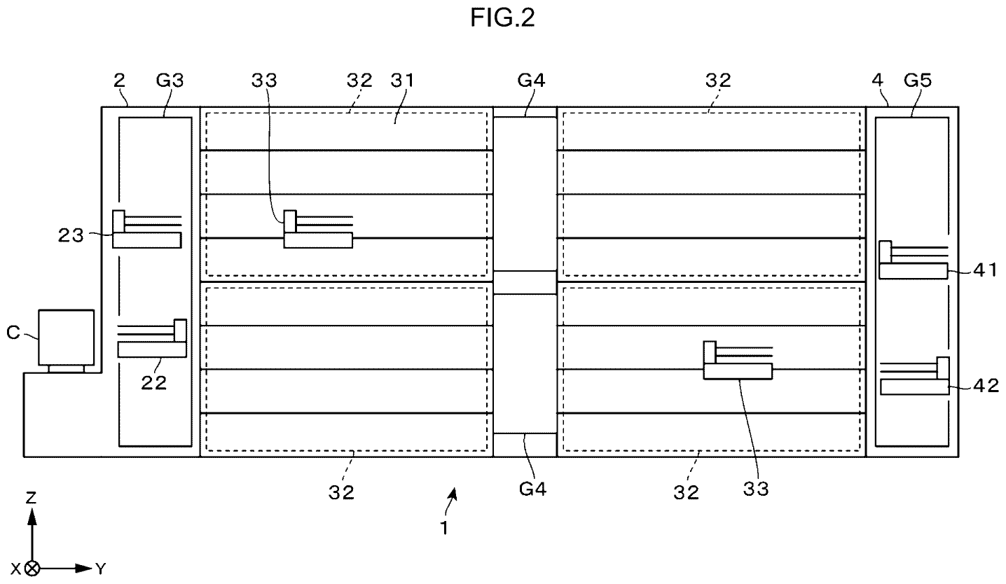

First, a configuration of the wafer processing system according to the present embodiment is described. FIGS. 1 and 2 are each of a plan view and a front view schematically illustrating an outline of a configuration of a wafer processing system 1. In the present embodiment, the wafer processing system 1 that is a photolithography processing system that performs formation processing and development processing of a resist film on a wafer W is described as an example.

As illustrated in FIG. 1, the wafer processing system 1 includes a cassette station 2 configured to carry in/out a cassette C accommodating a plurality of wafers W, and a processing station 3 including a plurality of various processing apparatuses that perform predetermined processing on the wafer W. The wafer processing system 1 is configured such that the cassette station 2, the processing station 3, and an interface station 4 are integrally connected to each other, the interface station 4 performing transfer of the wafer W between the processing station 3 and an exposure device (not illustrated) adjacent to the processing station 3 on the opposite side. Note that, although two processing stations 3 are installed between the cassette station 2 and the interface station 4 as illustrated in FIG. 1, one processing station 3 or three or more processing stations 3 may be installed.

The cassette station 2 is provided with a plurality of cassette placing pedestals 21 and wafer transfer devices 22 and 23. The cassette station 2 transfers the wafer between the cassette C placed on the cassette placing pedestal 21 and the processing station 3 by the wafer transfer device 22 or 23. Therefore, the wafer transfer devices 22 and 23 are each provided with a drive mechanism having a movement route in directions such as a horizontal direction (X direction and Y direction, a vertical direction (Z direction), and around a vertical axis (θ direction) as necessary, and may be provided with a drive mechanism having a movement route in all directions. At least one of the wafer transfer devices 22 and 23 can transfer the wafer to and from the cassette C, and can perform an operation of transferring the wafer to and from the processing station 3. Note that the operation of transferring the wafer to and from the processing station 3 means, for example, transferring the wafer to and from a third block G3 including a transfer device accessible by a wafer transfer device 33 in the processing station 3 described below. The third block G3 may include a plurality of transfer devices (not illustrated) arranged in the vertical direction.

Note that an inspection device (not illustrated) that inspects the wafer W may be provided at a position accessible by any one of the wafer transfer devices 22 and 23.

The processing station 3 is provided with a plurality of blocks, for example, first, second, and fourth three blocks G1, G2, and G4. As illustrated in FIG. 2, a plurality of layers 31 including the first and second blocks G1 and G2 are stacked in the vertical direction. For example, the first block G1 is provided on a front surface side of the processing station 3 (a negative side in the X direction in FIG. 1), and the second block G2 is provided on a back surface side of the processing station 3 (a positive side in the X direction in FIG. 1). The fourth block G4 is provided on the interface station 4 side of the processing station 3 (a positive side in the Y direction in FIG. 1) or at a connection portion with another adjacent processing station 3. The fourth block G4 may include a plurality of transfer devices arranged in the vertical direction. The above-described third block G3 may be provided in the processing station 3.

In the first block G1, a plurality of processing apparatuses, for example, a patterning film forming apparatus and a development processing apparatus both of which are not illustrated are arranged. The patterning film forming apparatus may include, for example, an antireflection film forming apparatus in addition to a resist film forming apparatus. For example, a plurality of processing apparatuses are arranged in the horizontal direction. Note that the number, arrangement, and type of the processing apparatuses can be freely selected.

In the patterning film forming apparatus and the development processing apparatus, for example, a predetermined processing solution or a predetermined gas is supplied onto the wafer W. As such, the patterning film forming apparatus forms a resist film used as a mask for forming a pattern of a film on a lower layer side, forms an antireflection film for efficiently performing light irradiation processing such as exposure processing, and the like. Meanwhile, in the development processing apparatus, an uneven shape is formed as the above-described mask by removing a part of the exposed resist film.

For example, in the second block G2, heat processing apparatuses (not illustrated) that perform heat processing such as heating or cooling of the wafer W are provided to be arranged in the vertical direction and the horizontal direction. In the second block G2, although not illustrated, a hydrophobization processing apparatus that performs hydrophobization processing for enhancing fixability between resist liquid and the wafer W and a peripheral exposure device that exposes an outer peripheral part of the wafer W are provided to be arranged in the vertical direction (Z direction in FIG. 2) and the horizontal direction. The number and arrangement of the heat processing apparatuses, the hydrophobization processing apparatuses, and the peripheral exposure devices can also be freely selected.

As illustrated in FIG. 1, a wafer transfer region 32 is formed in a region sandwiched between the first block G1 and the second block G2 in plan view. In the wafer transfer region 32, for example, the wafer transfer device 33 is disposed.

The wafer transfer device 33 includes a transfer arm 33a that is freely movable, for example, in the Y direction, a front-rear direction, the θ direction, and the vertical direction. The wafer transfer device 33 can move in the wafer transfer region 32 and transfer the wafer W to a predetermined device in the surrounding first block G1, second block G2, third block G3, and fourth block G4. When a plurality of processing stations 3 are provided, as illustrated in FIG. 1, the wafer transfer device 33 provided in the processing station 3 located on the interface station 4 side can transfer the wafer W to a predetermined device in a fifth block G5 described below, in addition to the first, second, and fourth blocks G1, G2, and G4.

For example, as illustrated in FIG. 2, a plurality of wafer transfer devices 33 are arranged vertically. One wafer transfer device 33 can transfer the wafer W to a predetermined device located at heights of the plurality of layers 31 on the upper side among the plurality of layers 31 stacked vertically. Another wafer transfer device 33 can transfer the wafer W to a predetermined device located at heights of the plurality of layers 31 located lower than the layers 31 on the upper side. A plurality of wafer transfer regions 32 are provided to enable the wafer W to be transferred as such. Note that the number of wafer transfer devices 33 and the number of layers 31 corresponding to one wafer transfer device 33 can be freely selected, such as providing the wafer transfer device 33 for each layer 31.

A shuttle transfer device (not illustrated) may be provided in the wafer transfer region 32, the first block G1, or the second block G2. The shuttle transfer device transfers the wafer W linearly between a space adjacent to one side of the processing station 3 and another space adjacent to the processing station 3 on the opposite side.

The interface station 4 is provided with the fifth block G5 including a plurality of transfer devices, and wafer transfer devices 41 and 42. The interface station 4 uses the wafer transfer device 41 or 42 to transfer the wafer W between the exposure device and the fifth block G5 to which the wafer W is transferred by the wafer transfer device 33. Therefore, the wafer transfer devices 41 and 42 are each provided with a drive mechanism having a movement route in directions such as the horizontal direction (X direction and Y direction), the vertical direction (Z direction), and around the vertical axis (θ direction) as necessary, and may be provided with a drive mechanism having movement routes in all directions. At least one of the wafer transfer devices 41 and 42 can support the wafer W and transfer the wafer W between the transfer device in the fifth block G5 and the exposure device.

A cleaning device that cleans a surface of the wafer W or the peripheral exposure device described above may be provided at positions accessible by any of the wafer transfer devices 41 and 42 in the interface station 4.

Although the inspection device may be provided in the cassette station 2 as described above, the inspection device may be provided also in the processing station 3 and the interface station 4 at a position accessible by any of the transfer arms (see 33, 41, and 42 in FIG. 1 or 2) provided in each of the processing station 3 and the interface station 4.

The above wafer processing system 1 is provided with a control device 100 as a controller. The control device 100 is, for example, a computer, and includes a program storage unit (not illustrated). The program storage unit stores a program for controlling the processing of the wafer W in the wafer processing system 1. The program storage unit also stores a program for controlling the operation of a drive system such as the above-described various processing apparatuses and transfer devices and realizing the wafer processing in the wafer processing system 1. The program includes a group of steps necessary for transferring and processing the wafer W in the wafer processing system 1, and the wafer W is transferred and processed by causing the control device 100 to output a control signal to each unit of the wafer processing system 1 by the program and control each unit as described above. Note that the above-described program is recorded in a computer-readable storage medium H, and may be installed from the storage medium H to the control device 100. The above-described storage medium H may include a ROM, a RAM, and a hard disk, but is not limited in structure and type, and may be temporary or non-temporary. Note that the control device 100 can include a unit that performs storage, reading, and execution of a program for realizing the wafer processing and communication related to the execution, and each unit may be disposed in a location that is inside or outside of the wafer processing system 1. The control device 100 may be one or a plurality of circuits, or may be provided as a whole or divided into units.

### Operation of Wafer Processing System

The wafer processing system 1 is configured as described above. Next, an example of the wafer processing performed using the wafer processing system 1 configured as described above is described.

First, the cassette C accommodating a plurality of wafers W is carried in the cassette station 2 of the wafer processing system 1 and is placed on the cassette placing pedestal 21. Next, the wafers W in the cassette C are taken out one by one by the wafer transfer device 22 or 23 and then transferred to the transfer device of the third block G3.

The wafer W transferred to the transfer device of the third block G3 is supported by the wafer transfer device 33 and transferred to the hydrophobization processing apparatus provided in the second block G2, and hydrophobization processing is performed. Next, the wafer transfer device 33 transfers the wafer W to the resist film forming apparatus to form a resist film on the wafer W, then transfers the wafer W to the heat processing apparatus for prebaking, and then transfers the wafer W to the transfer device of the fifth block G5. Note that, when a plurality of processing stations 3 are provided, as illustrated in FIGS. 1 and 2, the wafer W is once placed on the transfer device of the fourth block G4 before being transferred to the transfer device of the fifth block G5, and then is transferred between the plurality of wafer transfer devices 33. The wafer transfer device 33 may transfer the wafer W to the peripheral exposure device and exposure processing may be performed on a peripheral edge part of the wafer as necessary.

The wafer W transferred to the transfer device of the fifth block G5 is transferred to the exposure device by the wafer transfer devices 41 and 42, and exposure processing is performed on the wafer W in a predetermined pattern. Note that the wafer W may be cleaned by the cleaning device before the exposure processing.

The wafer W on which the exposure processing is performed is transferred to the transfer device of the fifth block G5 by the wafer transfer devices 41 and 42. Then, the wafer W is transferred to the heat processing apparatus by the wafer transfer device 33, and post-exposure baking processing is performed on the wafer W.

The wafer W on which the post-exposure baking processing is performed is transferred to the development processing apparatus by the wafer transfer device 33 and developed. After the development is completed, the wafer W is transferred to a heat processing apparatus 40 by the wafer transfer device 33 and post-baking processing is performed on the wafer W.

Thereafter, the wafer W is transferred to the transfer device of the third block G3 by the wafer transfer device 33 and transferred to the cassette C of a predetermined cassette placing pedestal 21 by the wafer transfer device 22 or 23 of the cassette station 2. As such, a series of photolithography steps is completed.

Note that the wafer processing system in the present disclosure is not limited to the configuration and the operation described above. For example, in the embodiment described above, the wafer processing system is directly connected to the exposure device and the wafer W is transferred between the interface station 4 and the exposure device, but the wafer processing system may not be directly connected to the exposure device. Here, for example, after the wafer W is transferred from the cassette station 2 to the processing station 3 and necessary processing is performed on the wafer W, the wafer W is transferred again to the cassette station 2 to be carried out to the outside of the system. Among the processing apparatuses, unnecessary processing apparatuses may not be provided in the wafer processing system, or processing in the unnecessary apparatuses may not be performed.

### Description of MOR

The resist film formed on the wafer W as a substrate by the resist film forming apparatus of the wafer processing system 1 described above is a resist film formed of a metal oxide resist (MOR). The MOR is, for example, a negative resist containing tin (Sn) as metal, and a ligand is connected to the metal during film formation. Here, “containing metal” means that metal is contained as an element, and does not mean that the metal is contained as an impurity. The resist film formed of MOR is exposed by the exposure device described above according to a pattern to be formed on the resist film.

### Description of Processing of Comparative Example

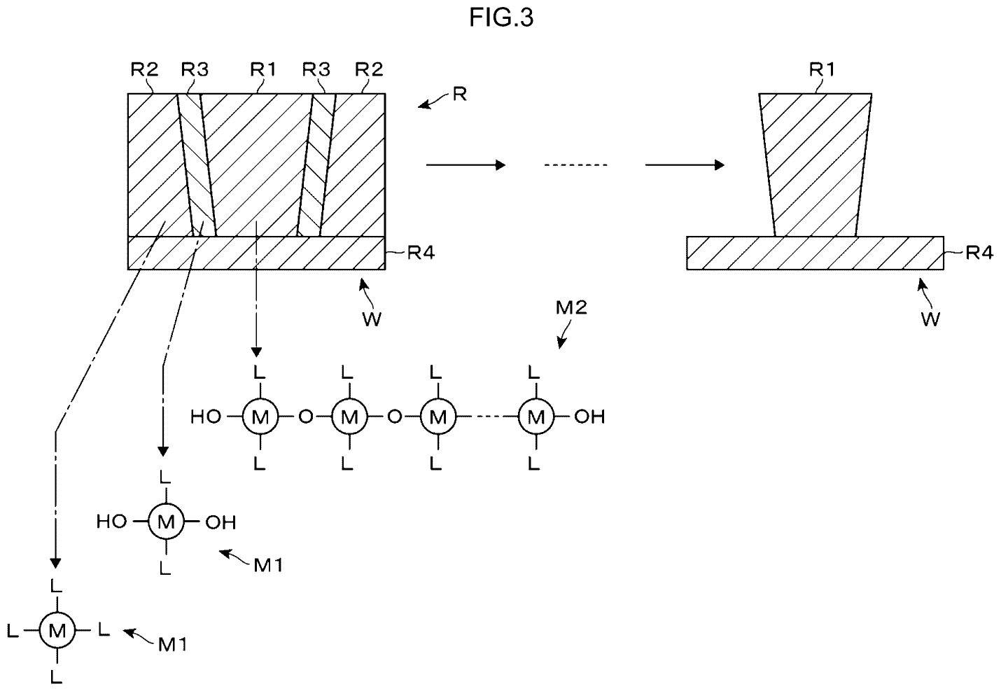

For easy understanding of processing performed by the wafer processing system 1 in the first embodiment, a comparative example is described in advance with reference to a side view of the wafer W illustrated in FIG. 3. In the description, a thickness direction of the wafer W is defined as the vertical direction, a side on which a resist film R is formed is defined as an upper side, and a side on which a lower layer film R4 to be etched using the resist film R as a mask is formed is defined as a lower side. The left side of FIG. 3 illustrates a state of the wafer W after exposure by the exposure device described above and before heat processing described as post exposure bake (PEB). For the resist film R, a region that is insoluble in a developing fluid to be supplied to the exposed wafer W is indicated as an insoluble region R1, and a region that is not exposed and soluble in the developing fluid is indicated as a soluble region R2.

The soluble region R2 contains a raw material compound M1 having metal M as a nucleus, and for the raw material compound M1, for example, a plurality of ligands L are bonded to the metal M. The insoluble region R1 is formed as a result of the raw material compounds M1 changing and bonding to each other. Specifically, the insoluble region R1 includes a reaction product M2 in which a part of the ligands L are released from the metal M contained in the raw material compound M1 by exposure, hydroxyl groups of the raw material compounds M1 are bonded to each other instead of the ligands L, the hydroxyl groups of the raw material compounds M1 are then dehydration-condensed, and the metals M are bonded to each other via oxygen. The reaction product M2 imparts insolubility with respect to the developing fluid in the insoluble region R1. An intermediate region R3 is interposed between the insoluble region R1 and the soluble region R2. As for the raw material compound M1 contained in the intermediate region R3, the hydroxyl groups in the metal M are bonded instead of the ligand L being released by exposure. However, since the supply amount of exposure energy is insufficient, the reaction product M2 is not generated in the intermediate region R3, and thus, the intermediate region R3 is soluble in the developing fluid.

Since the energy received by the resist film R during exposure decreases toward a bottom part of the resist film R, the insoluble region R1 has a shape having a smaller width toward the lower part side. Therefore, when PEB is performed and development is subsequently performed by supplying the developing fluid, as indicated by an arrow in FIG. 3, the insoluble region R1 remains as a convex part forming a resist pattern, but the convex part has a shape of which the width is narrowed toward the bottom part of the resist film R.

When the pattern of the resist film R is transferred to the lower layer film R4 by etching, a size of the width of the concave part formed in the lower layer film R4 corresponds to the size of a width of a bottom part of a concave part of the resist pattern. Therefore, when the convex part of the resist pattern is narrowed in width toward the lower side as described above (that is, the concave part of the resist pattern is widened in width toward the lower side), the width of the concave part transferred to the lower layer film R4 may become larger than a design value. When a thickness of the lower layer film R4 is relatively large, a thickness of the resist film R also becomes relatively large to prevent the resist film R from being lost during etching of the lower layer film R4. Therefore, a height of the convex part of the resist pattern (insoluble region R1) becomes relatively large, but then, when the lower side of the insoluble region R1 is narrowed in width toward the lower side as described above, there is a concern that the insoluble region R1 may be twisted or collapsed.

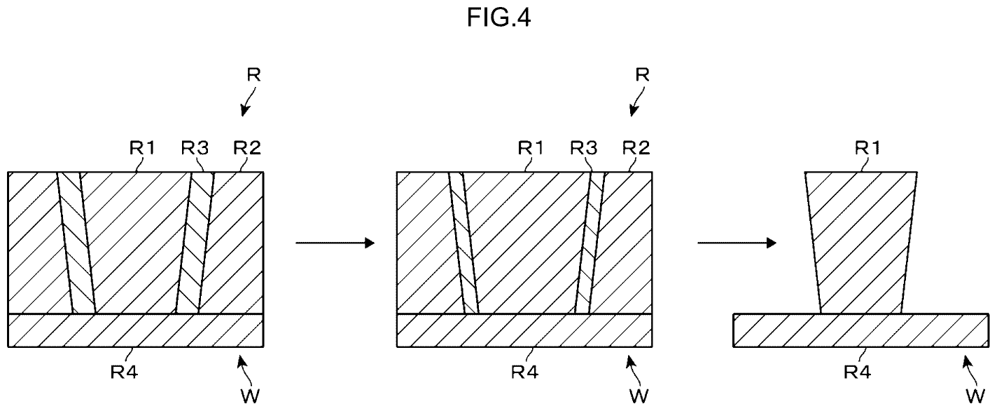

By setting the temperature of PEB relatively high, the progress of dehydration condensation between the hydroxyl group of the raw material compound M1 in the intermediate region R3 and the hydroxyl group remaining in the reaction product M2 of the insoluble region R1 is promoted. That is, as illustrated on the left side and the center of FIG. 4, a part of the intermediate region R3 changes into the insoluble region R1 from the insoluble region R1 side toward the soluble region R2 side. That is, as compared with a case in which the temperature during PEB is relatively low, reactivity of insolubilizing the resist film R2 with respect to the developing fluid is enhanced, and the insoluble region R1 is widened in width. However, even then, as illustrated on the right side of FIG. 4, the convex part of the resist pattern (=insoluble region R1) to be formed has a shape of which the width is narrowed toward the lower side, and thus the problem described above cannot be sufficiently solved.

From the above circumstances, it is required to form the insoluble region R1 to be approximate to a rectangle in side view by increasing perpendicularity with respect to the thickness direction of the wafer W and preventing the lower part side from becoming narrow with respect to the side wall of the insoluble region R1 after development. The wafer processing system 1 is configured to respond to such requirements when performing development on the wafer W using gas as a developing fluid.

As an outline of the processing of the first embodiment, processing is performed on the wafer W in the order of PEB, development, PEB, and development. That is, PEB and development are repeatedly performed in this order. Since the developing fluid supplied to the wafer W is gas, it is easy to switch between a state in which a substance exhibiting development reactivity remains on a front surface of the wafer W and a state in which the substance is removed from the front surface, as compared with a case in which a liquid flow of a developing solution is supplied to the wafer W as the developing fluid to form a liquid film on the wafer W. Since it is easy to switch, only a surface layer part of the resist film R is removed in a first development. That is, the soluble region R2 and the intermediate region R3 are only partially removed in a depth direction. Thereafter, by further removing the soluble region R2 and the intermediate region R3 in the depth direction in a second development, the soluble region R2 and the intermediate region R3 are entirely removed.

The first development is performed under processing conditions in which development reactivity with respect to the resist film R is higher than that in the second development. As seen in the width direction (left-right direction) of the pattern, as the development reactivity is higher, the insoluble region R1 is easily developed and dissolved, and as the development reactivity is lower, dissolution due to development hardly occurs even in the intermediate region R3. Therefore, by controlling the development reactivity for each time as such, it is possible to prevent the width of the lower part side of the convex part (insoluble region R1) of the resist pattern remaining after the second development from becoming narrower, and it is possible to form the insoluble region R1 into a shape that is approximate to a rectangle in side view. Here, developing gas is used instead of the developing solution in developing the resist film (that is, in removing a part of the film), but for convenience, removal by the gas may also be described as dissolution.

The processing is performed such that the temperature of the wafer W in a second PEB is higher than the temperature of the wafer W in a first PEB. Since the upper part side of the intermediate region R3 is removed during the second PEB, the width of the upper part side of the insoluble region R1 is prevented from becoming larger, but the width of the lower part side becomes larger. As such, the convex part of the resist pattern can have a shape that is more approximate to a rectangle in side view.

The first development described above corresponds to a first developing step, and the second development that is a final development corresponds to a second developing step. The first PEB and the second PEB correspond to each of a first heat processing step and a second heat processing step. In the present example, the PEB and the development are repeated once as described above (that is, PEB and development are each performed twice), but the number of times of repetition may be equal to or larger than two (that is, PEB and development may be each performed three or more times) as described below as another example. During repetition, development that is last performed may be described as a final development.

When the development is performed only twice as in the present example, the second development is the final development.

### Description of Developing Device for Performing Processing of First Embodiment

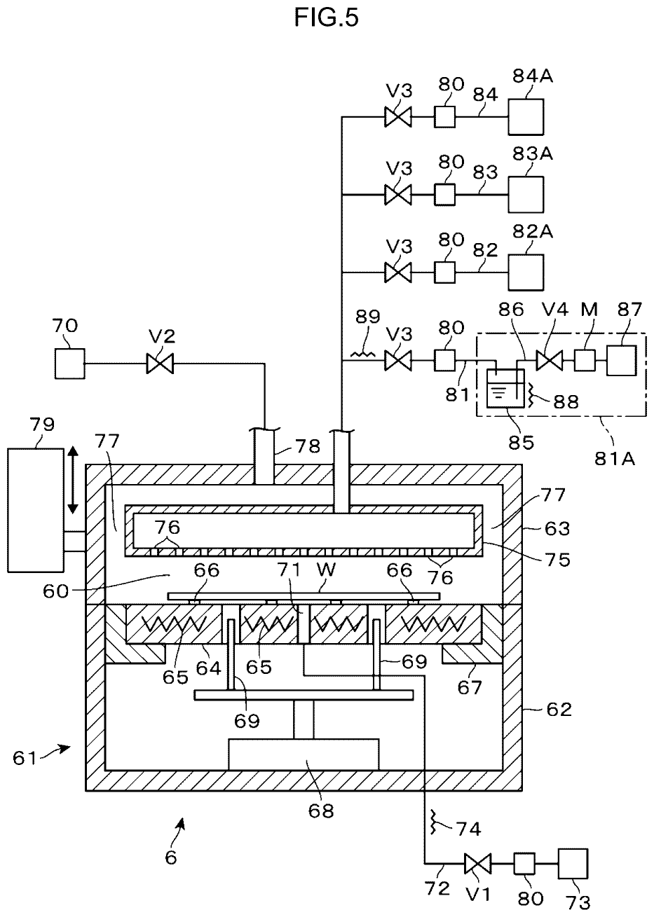

Next, a developing device 6 that can be provided as the developing device of the wafer processing system 1 described above and can repeatedly perform the PEB and the development as described above is described with reference to a longitudinal sectional side view of FIG. 5. The developing device 6 includes a processing container 61. The developing device 6 performs the development by supplying the developing gas to the wafer W positioned in a processing space 60 formed in the processing container 61 while the processing container 61 is closed. The PEB is also performed in the processing container 61. For example, the processing space 60 is maintained at an atmospheric pressure (standard atmospheric pressure) or a near atmospheric pressure, more specifically, for example, in a range of atmospheric pressure−10 kPa to atmospheric pressure+10 kPa, and the processing is performed on the wafer W.

The processing container 61 includes a lower member 62 configuring a bottom wall and a side wall on the lower part side, and an upper member 63 configuring an upper wall and a side wall on the upper part side, and when the upper member 63 is moved upward and downward by a vertical movement mechanism 79, the processing container 61 is opened and closed. First, the lower member 62 is described. The lower member 62 is provided with a heating plate 64 disposed above the bottom wall of the processing container 61. A heater 65 is embedded in the heating plate 64 that is a placement part of the wafer W and that forms a heat processing part for the heat processing of the wafer W.

On the upper surface of the heating plate 64, a plurality of support pins 66 for supporting the wafer W on the heating plate 64 are dispersedly provided. The wafer W placed on the heating plate 64 via the support pins 66 is heated to a desired temperature by controlling an output of the heater 65. Note that reference numeral 67 in the drawing denotes a heat insulating member provided around a side periphery of the heating plate 64. A vertical movement mechanism 68 is provided on a bottom wall of the processing container 61. Upper end parts of a plurality of pins 69 protrude and retract in the upper surface of the heating plate 64 according to vertical movement by the vertical movement mechanism 68, and the wafer W can be transferred between the heating plate 64 and the wafer transfer mechanism.

A discharge port 71 for gas is opened on the upper surface of the heating plate 64, and gas can be supplied to the back surface side (lower surface side) of the wafer W supported on the heating plate 64. The gas discharged from the discharge port 71 is purge gas for preventing the developing gas that reacts with the resist film R on the upper surface of the wafer W and contains the dissolved product of the resist film R from flowing to the lower surface of the wafer W, and the purge gas purges the back surface side of the wafer W and prevents adhesion of the dissolved product described above to the lower surface of the wafer W. Hereinafter, the gas discharged from the discharge port 71 may be described as back-surface-side purge gas.

The downstream side of a gas supply route 72 is connected to the discharge port 71, and the upstream side is connected to a gas supply mechanism 73 that supplies inert gas, specifically, for example, N₂ (nitrogen) gas as the back-surface-side purge gas to the gas supply route 72 via a valve V1 and a flow adjustment unit 80 in this order. Supply and supply stop of the back-surface-side purge gas from the discharge port 71 are switched by opening and closing of the valve V1. The flow adjustment unit 80 includes, for example, a mass flow controller, and adjusts a flow of the gas supplied to the downstream side of the gas supply route to a desired flow. A back surface supply route heater 74 is provided surrounding the gas supply route 72, and the temperature of the back-surface-side purge gas can be adjusted by heating the back-surface-side purge gas flowing through the gas supply route 72. The purpose of enabling temperature adjustment of the back-surface-side purge gas as such is described below.

Next, the upper member 63 is described. The upper member 63 is provided with a shower head 75 including a large number of discharge ports 76, and the gas is supplied from the discharge ports 76 toward the wafer W on the heating plate 64. A gap between the side wall of the processing container 61 and the side wall of the shower head 75 is configured as an exhaust port 77. An exhaust route 78 is connected to the upper wall of the processing container 61, and the downstream side of the exhaust route 78 is connected to an exhaust mechanism 70 via a valve V2. Exhaust from the exhaust port 77 and exhaust stop thereof are switched by opening and closing of the valve V2.

Gas supply routes 81, 82, 83, and 84 are connected to the shower head 75, and the valve V3 and the flow adjustment unit 80 are sequentially interposed toward the upstream side for each of the gas supply routes 81 to 84. By opening and closing of each valve V3, gas supply from the gas supply mechanism connected to the upstream side of the gas supply routes 81 to 84 to the shower head 75 and gas supply stop thereof are switched. A developing gas supply mechanism 81A is connected to the gas supply route 81 as the gas supply mechanism. The developing gas supply mechanism 81A includes a tank 85 storing the developing solution, a gas supply route 86 opened on a liquid layer of the developing solution in the tank 85, a valve V4 and the flow adjustment unit 80 sequentially interposed in the gas supply route 86 toward the upstream side, and a gas supply mechanism 87 connected to the upstream end of the gas supply route 86. The gas supply route 81 opens on a gas phase of the tank 85. The tank 85 includes a tank heater 88 that heats the developing solution stored in the tank 85.

Supply of the inert gas from the gas supply mechanism 87 to the tank 85 and supply stop thereof are switched by the opening and closing of the valve V4. The inert gas is, for example, the N₂ gas, and by supplying the N₂ gas from the gas supply mechanism 87, the developing solution in the tank 85 is vaporized by bubbling to become the developing gas. When the valve V4 is opened, the developing gas is discharged from the discharge port 76 of the shower head 75 to the processing space 60 along with the N₂ gas that is carrier gas supplied from the gas supply mechanism 87. A development supply route heater 89 that heats the gas flowing through the gas supply route 81 is provided, such that mixed gas of the developing gas and the carrier gas (N₂ gas) flowing toward the shower head 75 can be heated. Note that the developing solution stored in the tank 85 is, for example, acetic acid.

A developing gas supply mechanism 82A is connected to the gas supply route 82 as the gas supply mechanism. A developing gas supply mechanism 82A is configured similarly to the developing gas supply mechanism 81A. However, the tank heater 88 of the developing gas supply mechanism 82A is set to a higher temperature than the tank heater 88 of the developing gas supply mechanism 81A, and the developing gas supply mechanism 82A has higher vaporization efficiency of the developing solution than that of the developing gas supply mechanism 81A. Therefore, a concentration of the developing gas in the mixed gas (developing gas+carrier gas) supplied to the shower head 75 is higher when the gas is supplied from the gas supply route 81 than when the gas is supplied from the gas supply route 82. The developing gas supply mechanisms 81A and 82A, the gas supply routes 81 and 82, and the flow adjustment unit 80 and the valve V3 respectively interposed between the gas supply routes 81 and 82 configure a developing fluid supply unit.

An N₂ gas supply mechanism 83A that supplies, for example, the N₂ gas as the inert gas is connected to the gas supply route 83. A water vapor supply mechanism 84A is connected to the gas supply route 84. When humidity of the processing space 60 is high during the PEB, it is considered that a dehydration condensation reaction occurs between the hydroxyl group of the raw material compound M1 in the intermediate region R3 and the hydroxyl group remaining in the reaction product M2 in the insoluble region R1 as described in FIG. 3 via moisture in the processing space 60, and the width of the insoluble region R1 is widened. Meanwhile, when the humidity of the processing space 60 is low, widening does not occur. From such properties of the resist film R that is the MOR, the N₂ gas supply mechanism 83A and the water vapor supply mechanism 84A described above are provided to control the width of the insoluble region R1 by raising the humidity of the processing space 60 by supplying the water vapor and lowering the humidity of the processing space 60 by supplying the inert gas. In the present specification, the humidity means relative humidity unless otherwise specified.

Meanwhile, in the developing device 6, the PEB and the development are performed in the same processing container 61 as described above. The wafer W is continuously heated while being stored in the processing container 61, and until the final development is completed, heating while the developing fluid is not supplied is defined as the PEB, heating in a period during which the developing fluid is supplied is defined as the development, and the PEB and the development are distinguished from each other. In the following description, the intermediate region R3 is shown as a part of the soluble region R2, and the intermediate region R3 and the soluble region R2 may not be distinguished from each other.

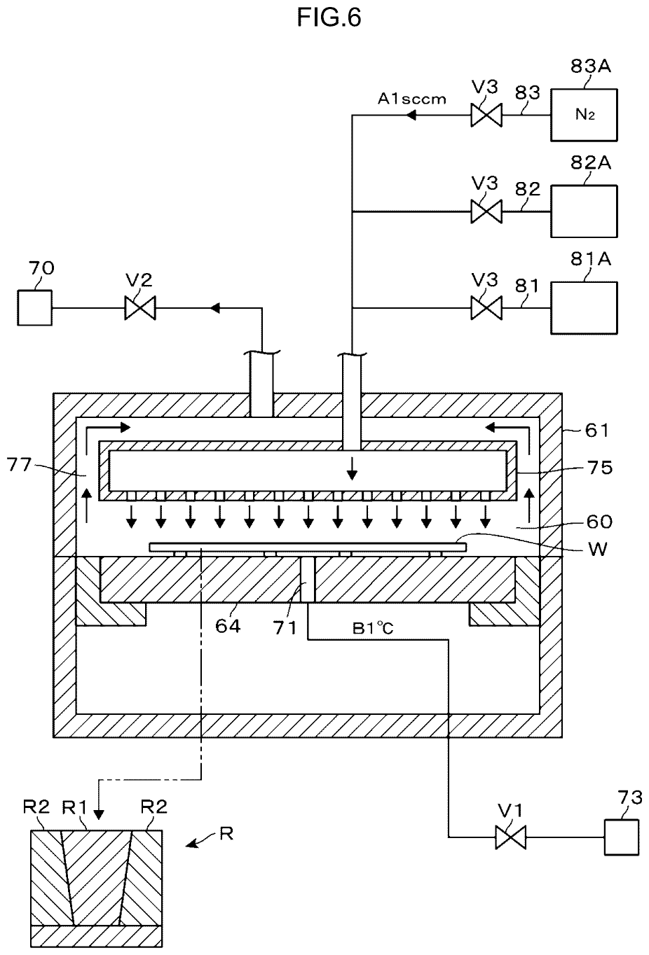

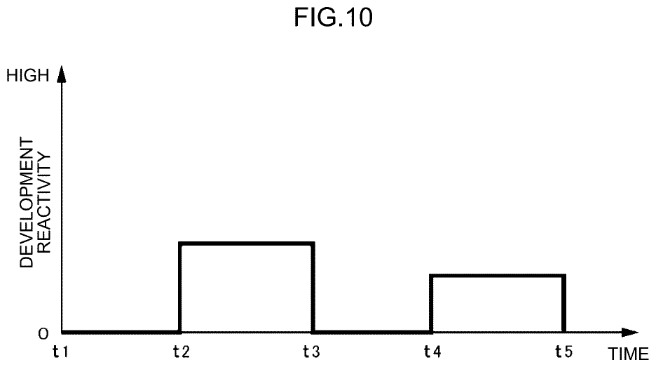

Hereinafter, a processing example of the wafer W is described with reference to FIGS. 6 to 9 in which changes in the resist film R are associated with the operation of the developing device 6. In each of the drawings, a longitudinal side surface of the resist film R is illustrated at the tip of a chain line arrow for the wafer W. In the processing example, some of the components described in FIG. 5 are not used. In the description of the processing example, a time chart of FIG. 10 is referred to as appropriate. The time chart shows transition of the level of the development reactivity of the atmosphere with respect to the resist film R in the processing space 60 according to the setting of various processing conditions.

First, the valve V3 of the gas supply route 83 is opened, and the N₂ gas is supplied from the N₂ gas supply mechanism 83A into the processing container 61 at a predetermined flow of A1 sccm, discharged from the shower head 75, and exhausted from the exhaust port 77. The wafer W is transferred into the processing container 61 while the temperature of the heating plate 64 is set to a predetermined temperature B1° C. by the heater 65, and the processing container 61 is closed to form the processing space 60. By supplying and exhausting the N₂ gas, the processing space 60 becomes an N₂ gas atmosphere. When the pin 69 (not illustrated in FIGS. 6 to 9) that supports the wafer W is moved downward, the wafer W is placed on the heating plate 64 (time t1) and is heated to the temperature B1° C. same as the heating plate 64. That is, as illustrated in FIG. 6, the first PEB is started. Due to the PEB, a predetermined chemical reaction proceeds in the resist film R. Since the processing space 60 has a relatively low humidity in the N₂ gas atmosphere, the reaction of widening the insoluble region R1 described in FIG. 4 is prevented.

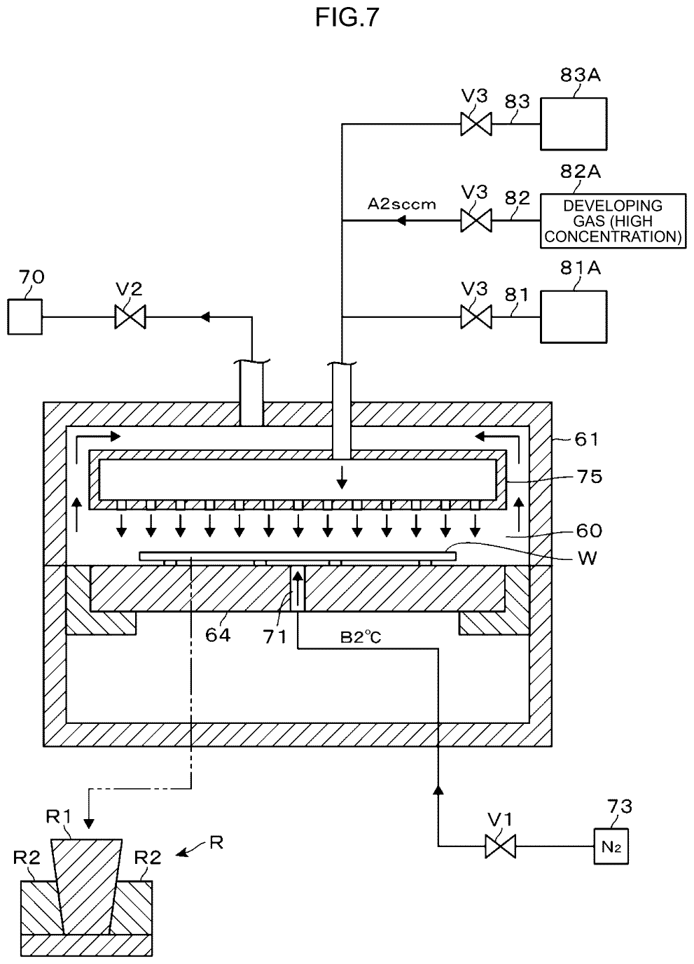

Thereafter, the temperature of the heating plate 64 is set to a predetermined temperature B2° C., the valve V3 of the gas supply route 82 is opened (time t2), and the mixed gas (developing gas and carrier gas) supplied from the developing gas supply mechanism 82A is supplied toward the inside of the processing container 61 at a predetermined flow A2 scccm and discharged from the shower head 75. That is, as illustrated in FIG. 7, the first development is started. At time t2, the valve V3 of the gas supply route 83 is closed to stop the supply of the N₂ gas from the N₂ gas supply mechanism 83A to the processing space 60, and the valve V1 is opened to start the discharge of the back-surface-side purge gas from the discharge port 71 of the heating plate 64.

The surface layer part of the soluble region R2 of the wafer W heated to B2° C. is removed by the developing gas. As described above, since the developing gas supply mechanism 82A has relatively high vaporization efficiency with respect to the developing solution, the concentration of the developing gas in the mixed gas is relatively high. Therefore, an atmosphere having relatively high development reactivity is formed in the processing space 60. Therefore, the side surface of the upper part side of the insoluble region R1 exposed by removing the soluble region R2 is also slightly scraped by reacting with the developing gas.

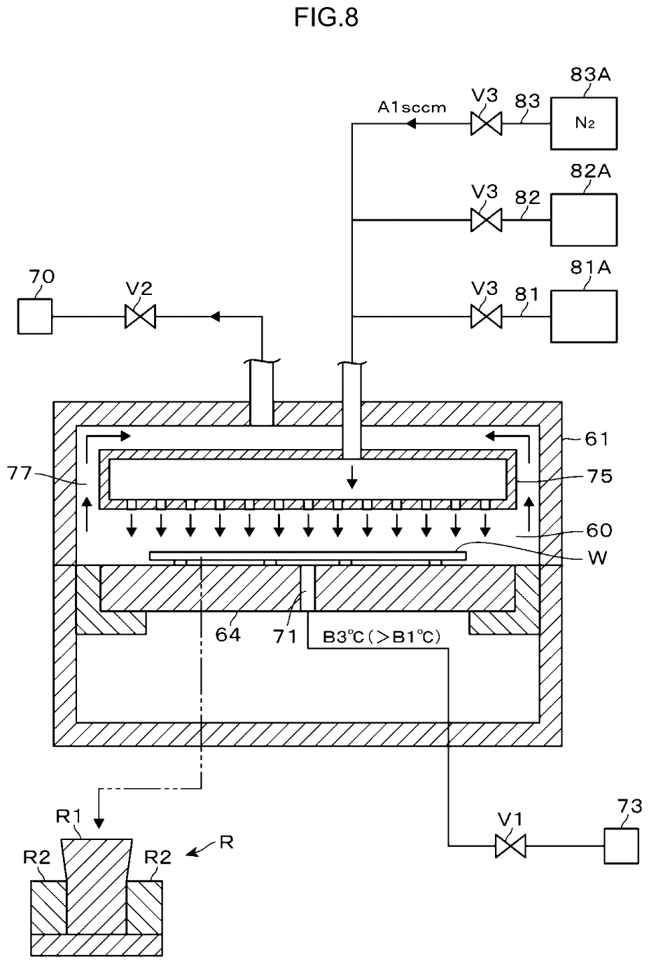

When the soluble region R2 is removed to a predetermined depth, the valve V3 of the gas supply route 82 is closed and the valve V3 of the gas supply route 83 is opened, and the N₂ gas from the N₂ gas supply mechanism 83A is supplied again to the processing space 60 at a predetermined flow A1 sccm instead of the mixed gas containing the developing gas described above. While switching the opening and the closing of each of the valves V3, the temperature of the heating plate 64 is changed to B3° C. higher than B1° C. in the first PEB (time t3), and the wafer W is heated to B3° C. That is, when the first development is completed, the second PEB is started (FIG. 8), the developing gas in the processing space 60 is purged and removed, and the wafer W is heated in the N₂ gas atmosphere. At time t3 described above, the valve V1 is closed, and the discharge of the back-surface-side purge gas from the discharge port 71 is also stopped.

As described above, in the second PEB, the wafer W is heated to a higher temperature than in the first PEB. Therefore, the hydroxyl group of the reaction product M2 contained in the lower part side of the insoluble region R1 that is in contact with the soluble region R2 and the hydroxyl group of the raw material compound M1 contained in the soluble region R2 (more specifically, the intermediate region R3) are dehydration-condensed. As a result, a range containing the reaction product M2 is widened, and the lower part side of the insoluble region R1 is widened.

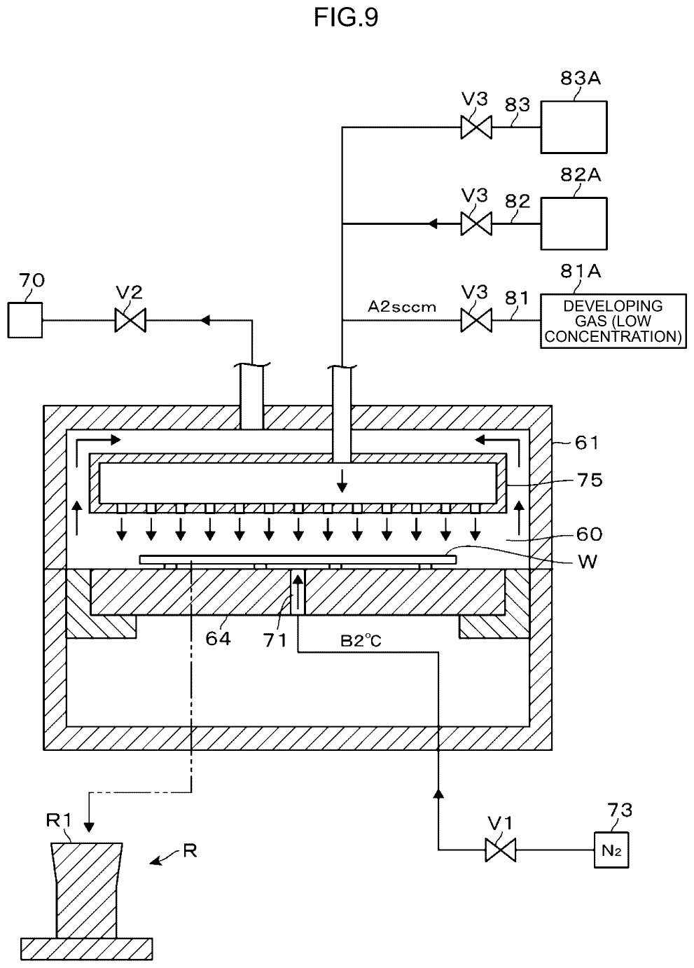

The temperature of the heating plate 64 is set to the predetermined temperature B2° C., the valve V3 of the gas supply route 81 is opened (time t4), and the mixed gas of the developing gas and the carrier gas supplied from the developing gas supply mechanism 81A is supplied toward the inside of the processing container 61 at the predetermined flow A2 scccm and discharged from the shower head 75. That is, as illustrated in FIG. 9, the second development is started. Note that output of a development supply route heater 89 is controlled such that the temperature of the mixed gas supplied to the processing space 60 in the second development is the same as the temperature of the mixed gas supplied to the processing space 60 in the first development. The temperature B2° C. of the heating plate described above is set to be, for example, equal to or higher than 120° C., to prevent liquefaction of the acetic acid that is the developing gas, and is lower than B1° C. and B3° C. that are temperatures at each PEB. At time t4 described above, the valve V3 of the gas supply route 83 is closed to stop the supply of the N₂ gas from the N₂ gas supply mechanism 83A to the processing space 60, and the valve V1 is opened to start the discharge of the back-surface-side purge gas from the discharge port 71 of the heating plate 64.

The soluble region R2 remaining on the wafer W heated to B2° C. is removed downward by the developing gas. As described above, the vaporization efficiency of the developing solution in the developing gas supply mechanism 81A is lower than that in the developing gas supply mechanism 82A, and thus the concentration of the developing gas in the mixed gas is relatively high. Therefore, in the processing space 60, an atmosphere having lower development reactivity than that in the first development is formed. Therefore, the removal of the soluble region R2 proceeds while scraping of the side surface at each height of the insoluble region R1 exposed by the removal of the soluble region R2 is prevented.

For example, when removal is performed overall such that the lower layer film R4 is exposed, the valve V3 of the gas supply route 81 is closed, and the valve V3 of the gas supply route 83 is opened. The N₂ gas from the N₂ gas supply mechanism 83A is supplied again to the processing space 60 instead of the mixed gas containing the developing gas described above, and the developing gas in the processing space 60 is purged and removed. The valve V1 is closed, and the discharge of the back-surface-side purge gas is stopped. Then, the processing container 61 is opened, and the wafer W is carried out.

As described above, in the first embodiment, when the development is performed stepwise, processing conditions having high development reactivity are set in the first development, and the upper part side of the exposed insoluble region R1 is promoted to be dissolved from the side. In the second development in which the upper part side and the lower part side of the insoluble region R1 are exposed, processing conditions having lower development reactivity than that in the first development are set, and the dissolution from the side of each of the upper part side and the lower part side is prevented. The processing conditions are set such that the reaction in which the insoluble region R1 is widened is prevented in the first PEB, and the reaction in which the insoluble region R1 is widened is promoted in the second PEB as compared with the first PEB. When the processing is performed by setting the processing conditions as such, the convex part (insoluble region R1) of the pattern of the resist film R formed after development can be prevented from narrowing in width on the lower part side than on the upper part side, and can have a shape that is approximate to a rectangle in side view.

### Variation of Adjustment of Development Reactivity

In the example illustrated in FIGS. 6 to 9, the parameter of the processing condition to be changed for the development reactivity of the processing space 60 between the second development and the first development is the concentration of the developing gas contained in the mixed gas supplied to the processing space 60. That is, the processing condition in which the concentration of the developing fluid in the gas supplied into the processing container 61 storing the wafer W is set to be higher in the first development (first developing step) than in the second development (second developing step). The parameter of the processing condition to be changed is not limited to the concentration of the developing gas as described above. For example, the processing condition is set such that the heating temperature of the wafer W in the first development is higher than the heating temperature of the wafer W in the second development. Accordingly, more heat energy is supplied to the developing gas and the resist film R in the first development, and the development reactivity in the first development can be made higher than the development reactivity in the second development. To make the temperature of the wafer W different in each development as described above, the temperature of the heating plate 64 may be used as the parameter described above.

A specific example of processing when the development reactivity is made different depending on the temperature of the heating plate 64 is described. In the processing of FIGS. 6 to 9, the first development and the second development are performed by supplying gas from the developing gas supply mechanism 81A, and the temperature of the heating plate 64 in the second development (time t4 to time t5) is set to a temperature B4° C. lower than the temperature (B2° C.) of the heating plate 64 in the first development (time t2 to time t3). Except for such differences, the processing is performed similarly to the example illustrated in FIGS. 6 to 9. By the temperature setting of the heating plate 64 described above, the temperature of the wafer W in the first development is higher than the temperature of the wafer W in the second development, such that the development reactivity in the first development can be made higher than the development reactivity in the second development.

Note that, when the temperature of the wafer W is made different between the first development and the second development as described above, the temperature difference is not limited to depending on the temperature setting of the heating plate 64. Instead of setting the temperature of the heating plate 64 to be different between when the first development is performed and when the second development is performed, the output of the back surface supply route heater 74 may be controlled such that the temperature of the back-surface-side purge gas in the first development becomes higher than that in the second development.

The temperature of the developing gas supplied to the processing space 60 may be used as the parameter for making the development reactivity different. As an example of such processing of changing the temperature of the developing gas, the processing in FIGS. 6 to 9 is changed such that the first development and the second development are performed using only the mixed gas from the developing gas supply mechanism 81A instead of the mixed gas from the developing gas supply mechanisms 81A and 82A. By controlling the output of the development supply route heater 89 such that the temperature of the mixed gas from the developing gas supply mechanism 81A in the first development becomes higher than that in the second development, the temperature of the developing gas in the mixed gas is made different between the first development and the second development.

Examples of other parameters for making the development reactivity different include the flow of the developing gas supplied to the processing space 60, and the flow in the first development may be set to be larger than that in the second development. As an example of such processing of making the flow of the developing gas different, the processing in FIGS. 6 to 9 is changed such that the first development and the second development are performed using only the mixed gas from the developing gas supply mechanism 81A instead of the mixed gas from the developing gas supply mechanisms 81A and 82A. Then, the operation of the flow adjustment unit 80 in the gas supply route 81 is controlled such that the mixed gas is supplied at the flow A2 sccm in the first development and the mixed gas is supplied at a flow A3 sccm smaller than the flow A2 sccm in the second development. Since the flow of the mixed gas supplied to the processing space 60 in the first development is larger than that in the second development, the flow of the developing gas contained in the mixed gas in the first development also becomes larger than that in the second development.

Meanwhile, in the processing of the wafer W, when the supply amount of the mixed gas containing the developing gas from the developing gas supply mechanism 81A in the second development (in the next development) is made smaller than that in the first development (in the previous development), for example, it is preferable to supply the N₂ gas that is the inert gas from the N₂ gas supply mechanism 83A to the processing space 60 and compensate for the amount of difference. That is, the flow of the developing gas supplied to the processing space 60 in the next development is made smaller than that in the previous development, but the flow of the inert gas supplied to the processing space 60 in the next development is made larger than that in the previous development. Note that the flow of the inert gas is a total of the flow of the carrier gas (N₂ gas) in the mixed gas supplied from the developing gas supply mechanism 82A and the flow of the N₂ gas supplied from the N₂ gas supply mechanism 83A.

By setting a relationship of the flow of each gas between the previous development and the next development as such, the concentration of the developing gas in the gas supplied to the processing space 60 in the next development becomes lower than that in the previous development.

Therefore, after the next development is performed, the purge of the developing gas remaining in the processing space 60 is quickly completed, and the subsequent processing can be performed. That is, the wafer W to be transferred to the processing space 60 next can be processed.

Note that, although the previous development and the subsequent development are described as the first development and the second development, the PEB and the development may be repeated and performed three or more times as described below. Then, the subsequent processing described above may be processing on the wafer W to be transferred to the processing space 60 next, or the PEB and the development may be processing on the same wafer W as the wafer W processed until now. That is, (n+1)-th (n is a positive integer) PEB and development may be performed on the wafer W on which n-th PEB and development was performed. As described above, when the subsequent processing is the (n+1)-th PEB and development, by reducing the concentration of the developing gas in the n-th development, the developing gas that enters the fine concave part of the resist pattern in the (n+1)-th PEB is quickly and reliably removed by purging with the N₂ gas supplied to the processing space 60. Therefore, the (n+1)-th development is performed without being affected by the remaining developing gas. Therefore, the shape of the resist pattern can be preferably made closer to a desired shape.

### Combination of Plurality of Developing Parameters

As described above, there are a plurality of parameters of the processing condition related to the development reactivity. In each of the processing examples described above, only one processing condition is set to different values between the first development and the second development, but a plurality of processing conditions may be set to different values between the first development and the second development such that the development reactivity in the first development is made higher than the development reactivity in the second development.

The example of setting a plurality of parameters to different values as described above is not limited to setting all of the plurality of parameters such that the development reactivity in the first development becomes lower than the development reactivity in the second development, and any of the parameters may be set such that the development reactivity in the second development becomes higher than the development reactivity in the first development. That is, by canceling an effect of increasing the development reactivity in the second development by changing a certain parameter to be different by an effect of reducing the development reactivity in the second development by changing another parameter to be different, the development reactivity in the first development may be made lower than the development reactivity in the second development.

Specifically, the temperature of the wafer W in the second development is set to be higher than the temperature of the wafer W in the first development, and for the concentration of the developing gas in the mixed gas supplied to the processing space 60, the concentration in the first development is set to be higher than the concentration in the second development. That is, it is assumed that the temperature of the wafer W is set to have higher development reactivity in the second development. The wafer W may be processed such that the influence of the temperature of the wafer W is offset by the influence of the concentration of the developing gas and the development reactivity in the first development becomes higher than the development reactivity in the second development.

Note that it is specified by experiment that the development reactivity in the first development is higher than the development reactivity in the second development. In the experiment, a plurality of wafers W on which resist film formation, exposure, and PEB are sequentially performed under the same processing conditions are prepared. One wafer W is developed under the processing conditions in the first development, and another wafer W is developed under the processing conditions in the second development. When the time of the first development is different from the time of the second development, the developing time of one wafer W is made different from the developing time of another wafer W in the experiment as well by an amount corresponding to a difference in time. Then, the developing speed per unit time (speed of etching in the depth direction of the soluble region R2 of the resist film R) is calculated for each of the wafers W, and when the developing speed of one wafer W is higher than the developing speed of another wafer W, the development reactivity is higher for the processing condition in the first development than in the second development. The development may be performed three or more times, and then, a relationship of the level of the development reactivity for each development is also specified by a similar experiment.

### Variation of Adjustment of PEB

In the processing examples illustrated in FIGS. 6 to 9, since the reaction of widening the insoluble region R1 further proceeds in the second PEB than in the first PEB, the temperature of the heating plate 64 in the second PEB is set to be higher than the temperature of the heating plate 64 in the first PEB, and the temperature of the wafer W in the second PEB was set to be higher than that in the first PEB. In order to make the reaction of widening the insoluble region R1 proceed more rapidly in the second PEB than in the first PEB, the method is not limited to making the temperature of the wafer W different at each PEB as described above.

As a specific example, in the processing examples of FIGS. 6 to 9, the temperatures of the heating plate 64 at each PEB are set to the same temperature of B1° C. As such, instead of making the temperatures of the heating plate 64 constant at each PEB, the flows of the N₂ gas supplied to the processing space 60 is made different at each PEB. For example, the flow is set to A1 sccm in the first PEB as described in FIG. 6, and set to A3 sccm smaller than A1 sccm in the second PEB. By controlling the flow as such, the concentration of the N₂ gas in the processing space 60 in the first PEB is made higher than the concentration of the inert gas in the processing space 60 in the second PEB. By adjusting the concentration of the N₂ gas that is the inert gas as such, assuming that the atmosphere slightly enters the processing space 60 from the outside of the processing container 61, the humidity of the processing space 60 in the second PEB is higher than that in the first PEB, and the reaction of widening the insoluble region R1 can further proceed in the second PEB than in the first PEB.

Note that, when the flow of the N₂ gas supplied to the processing space 60 is made different at each PEB as described above, the flow A1 sccm of the N₂ gas in the first PEB may be 0 sccm. That is, the PEB is not limited to being performed while the gas is supplied to the processing space 60. Hereinafter, the reaction of widening the insoluble region R1 may be simply described as a widening reaction.

To make the humidity of the processing space 60 in the second PEB higher than the humidity of the processing space 60 in the first PEB, the flow of the water vapor supplied from the water vapor supply mechanism 84A to the processing space 60 may be adjusted instead of adjusting the flow of the N₂ gas supplied to the processing space 60 as described above. Specifically, the water vapor is supplied to the processing space 60 at A4 sccm in the first PEB, and the water vapor is supplied to the processing space 60 at A5 sccm that is a flow larger than A4 sccm in the second PEB. Note that the flow A4 sccm of water vapor in the first PEB may be 0 sccm.

In the process examples of FIGS. 6 to 9, the back-surface-side purge gas is set to be not supplied at each PEB, but the back-surface-side purge gas may be set to be supplied. When the back-surface-side purge gas is supplied at each PEB, the parameter related to the back-surface-side purge gas that is the inert gas and heating gas can be set as the parameter that makes widening reactivity different. As a specific example of such processing, in the processing examples of FIGS. 6 to 9, the temperatures of the heating plate 64 at each PEB are set to the same temperature of B1° C. As such, instead of making the temperature of the heating plate 64 constant at each PEB, the temperature of the back-surface-side purge gas is made different at each PEB. Then, by controlling the output of the heater 74, the back-surface-side purge gas of F1° C. is discharged from the discharge port 71 in the first PEB, and the back-surface-side purge gas of F2° C. higher than F1° C. is discharged from the discharge port 71 in the second PEB. Since the amount of heat from the heating plate 64 and the amount of heat from the back-surface-side purge gas are added, the temperature of the wafer W in the second PEB is higher than that in the first PEB, and thus the widening reactivity in the second PEB is higher than that in the first PEB.

The flow may be changed instead of changing the temperature of the back-surface-side purge gas at each PEB. Specifically, by controlling the operation of the flow adjustment unit 80 of the gas supply route 72, the back-surface-side purge gas is supplied to the processing space 60 at F3 sccm in the first PEB, and the back-surface-side purge gas is supplied to the processing space 60 at F4 sccm larger than F3 sccm in the second PEB. By changing the flow of the back-surface-side purge gas between the first PEB and the second PEB as such, the concentration of the inert gas in the processing space 60 in the second PEB is increased and the humidity of the inert gas therein is reduced as compared with those in the first PEB. Therefore, the widening reactivity is higher in the second PEB than in the first PEB.

### Combination of Parameters for Plurality of PEBs

As described above, there are a plurality of parameters of processing conditions related to the widening reactivity of the insoluble region R1 during the PEB. One parameter may be set to different values between each PEB, or a plurality of parameters may be set to different values between each PEB.

The example of setting a plurality of parameters to different values as described above is not limited to setting all of the plurality of parameters such that the widening reactivity in the second PEB becomes higher than the widening reactivity in the first PEB. Any of the parameters may be set such that the widening reactivity in the first PEB becomes higher than the widening reactivity in the second PEB. That is, by canceling an effect of increasing the widening reactivity in the first PEB by changing a certain parameter to be different by an effect of increasing the widening reactivity in the second PEB by changing another parameter to be different, the widening reactivity in the second PEB may be made higher than the widening reactivity in the first PEB.

As a specific example, the humidity of the processing space 60 in the first PEB is set to be higher than that in the second PEB, and the temperature of the wafer W in the second PEB is set to be higher than that in the first PEB. That is, it is assumed that the humidity is set to have higher widening reactivity in the first PEB. The wafer W may be processed such that the influence of the humidity of the wafer W is offset by the influence of the temperature of the wafer W and the widening reactivity in the second PEB becomes higher than the widening reactivity in the first PEB.

Note that it is specified by experiment that the widening reactivity in the second PEB is higher than the widening reactivity in the first PEB. In the experiment, a plurality of wafers W on which resist film generation and exposure are performed under the same processing conditions are prepared. The PEB is performed on one wafer W under the processing conditions in the first PEB, and the PEB is performed on another wafer W under the processing conditions in the second PEB. When the execution time of the first PEB is different from the execution time of the second PEB, the time of the PEB of one wafer W is made different from the time of the PEB of another wafer W in the experiment as well by an amount corresponding to a difference in time. Then, the wafers W are developed under the same conditions, and when the width of the insoluble region R1 of another wafer W is larger than that of one wafer W, the widening reactivity at the processing condition in the second PEB is higher than in the first PEB. The PEB may be performed three or more times, and then, a relationship of the level of the widening reactivity at each PEB can also be specified by the above experiment.

### Repeated Processing and Development Reactivity of Each Time

In the processing of FIGS. 6 to 9, the number of times of repetition of the PEB and the development is set to one (the PEB and the development are each performed twice), but the number of times of repetition may be set to two (the PEB and the development may be each performed three times), and the soluble region R2 may be etched stepwise downward. That is, more developing steps may be performed between the first developing step that is the first development and the second developing step that is the final development. The processing may be performed by setting the number of times of repetition to be larger than two. As the number of times of repetition is set larger, it is preferable that the insoluble region R1 after development can be formed to be approximate to a rectangle in side view. However, from the viewpoint of increasing a throughput of the developing device 6, the number of times of repetition is preferably small.

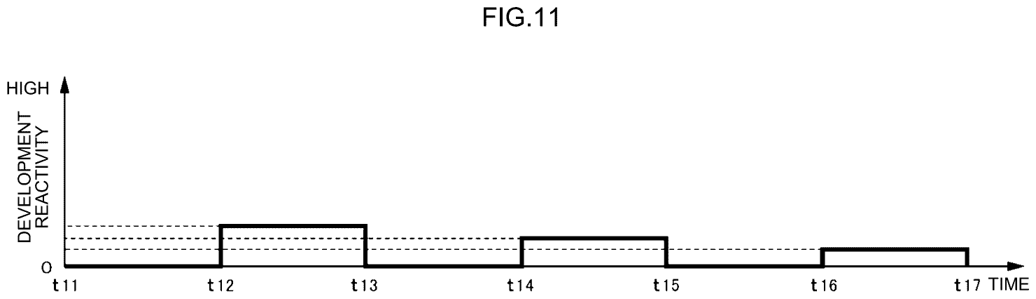

When the number of times of repetition of the PEB and the development is set to two or more times and the development is performed three or more times as described above, the processing conditions described above may be set such that the development reactivity is different for each development. For example, when the development is performed three times, the processing conditions can be set such that the development reactivity gradually decreases as the number of times of development increases, as illustrated in FIG. 11 and the development reactivity is differently obtained for each development.

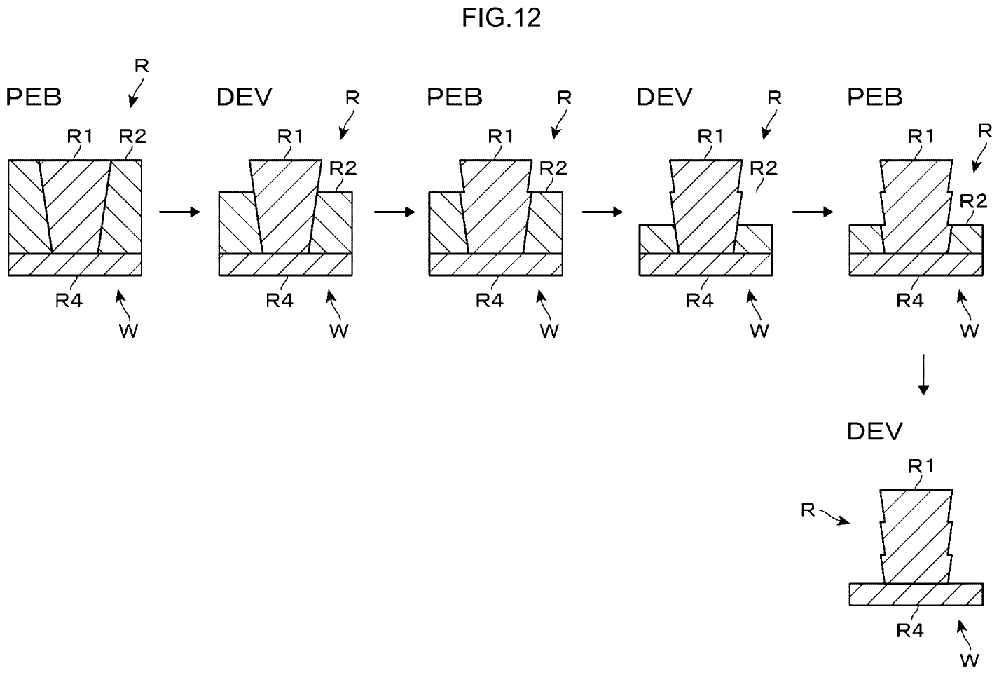

Similarly to FIG. 10, FIG. 11 is a time chart showing transition of the level of the development reactivity of the atmosphere with respect to the resist film R in the processing space 60. In the chart, a period from time t11 to time t12 is a period of the first PEB, a period from time t12 to time t13 is a period of the first development, a period from time t13 to time t14 is a period of the second PEB, a period from time t14 to time t15 is a period of the second development, a period from time t15 to time t16 is a period of the third PEB, and a period from time t16 to time t17 is a period of the third development. FIG. 12 is a longitudinal sectional side view of the wafer W showing a change in the resist film R when processing is performed by controlling the development reactivity as illustrated in FIG. 11, and development is indicated as DEV.

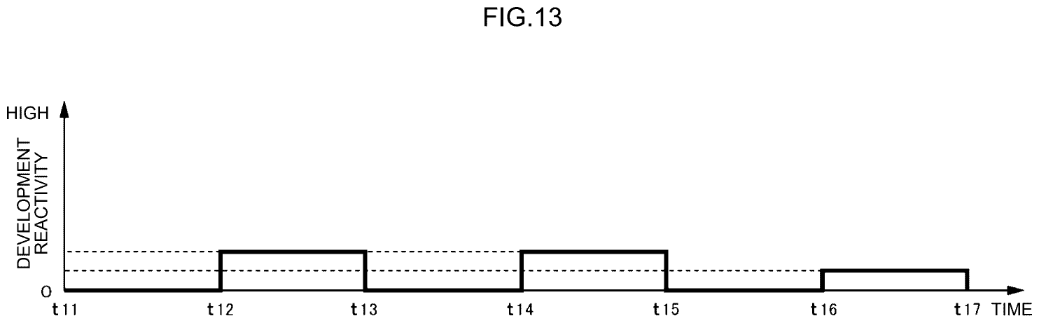

When the development is performed three or more times, the processing conditions may be set such that the development reactivity is the same for a plurality of consecutive developments. As a specific example, for example, when the development is performed three times, the processing conditions may be set such that the same development reactivity is obtained for the first development and the second development, as illustrated in FIG. 13. The processing conditions may be set such that the same development reactivity is obtained for the second development and the third development. However, as illustrated in FIG. 11, by gradually reducing the development reactivity as the number of times of development increases, the side wall of the insoluble region R1 is further dissolved toward the upper part side and the shape of the insoluble region R1 after development can be formed to be preferably more approximate to a rectangle in side view.

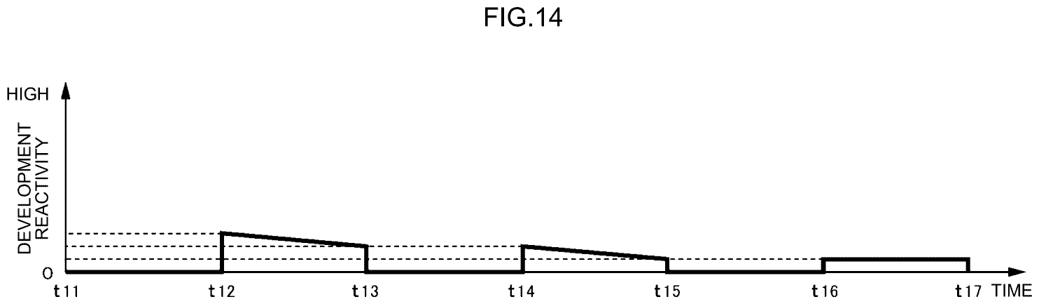

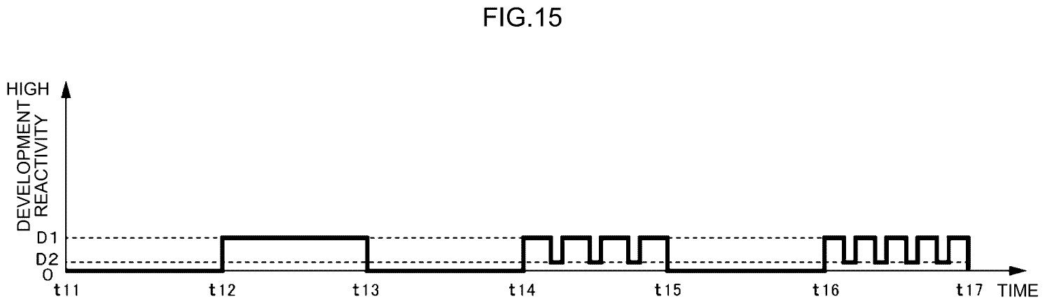

In the example illustrated in FIG. 11, the processing conditions are set such that the development reactivity is the same during the same development, but the processing conditions may be set such that the development reactivity is changed during the same development. That is, the development reactivity may be changed by displacing the above-described parameters during development. As in the example of FIG. 11, when the PEB and the development are performed three times, specific examples of changing the development reactivity during the same development are illustrated in FIGS. 14 and 15.

Differences between the processing examples of FIGS. 14 and 15 and the processing example of FIG. 11 are described. In the example illustrated in FIG. 14, the development reactivity gradually decreases during the first development and the second development. The development reactivity is the same at the end of the first development (time t13) and at the start of the second development (time t14), and the development reactivity is the same at the end of the second development (time t15) and the start of the third development (time t16).

In the example illustrated in FIG. 15, the development reactivity is set to be maintained at D1 during the first development, but the development reactivity is repeatedly changed between D1 and D2 lower than D1 during the second development and the third development. The lengths of the periods of the first to third developments are the same, and the third development has a larger number of repetition of the development reactivity changing between D1 and D2 than that of the second development, such that the period during which the development reactivity is D2 is longer in the third development. In the processing examples in FIGS. 14 and 15 as well, the magnitude of the development reactivity is the first development>the second development>the third development, and thus the development reactivity gradually decreases as the number of times of development increases as in the example in FIG. 11. As illustrated in the examples of FIGS. 14 and 15, the development reactivity may not be set to be constant during each development.

### Regarding Final Development

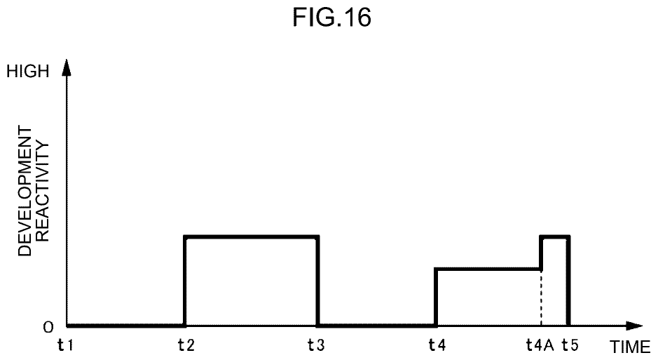

FIG. 16 is a chart showing transition of the development reactivity when processing of repeating the PEB and the development twice is performed as described with reference to FIG. 10. Therefore, the final development of the processing illustrated in FIG. 16 is the second development. As a difference from the processing of FIG. 10, in the processing of FIG. 16, the processing conditions are changed such that the development reactivity increases at time t4A after a predetermined time is elapsed from time t4 at which the final development is started. That is, at least one parameter related to the development reactivity described above is changed. After time t4A, the supply of the developing gas is stopped at time t5, similarly to the processing of FIG. 10, and the development reactivity becomes 0.

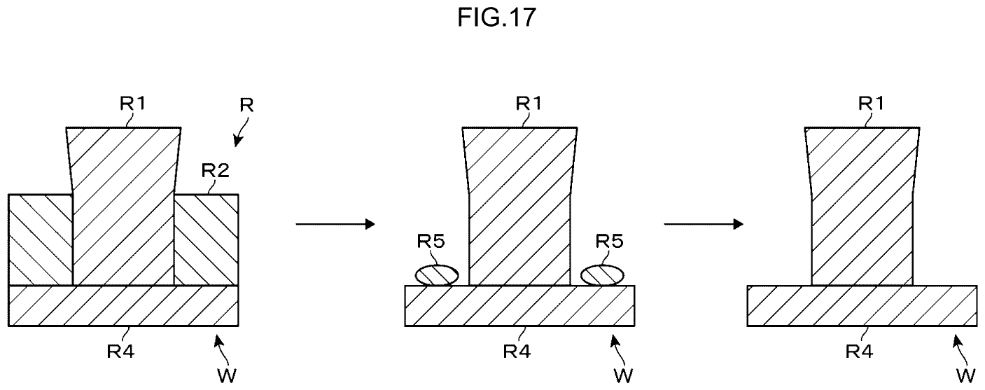

The reason of increasing the development reactivity during the final development as described above is that, when the development reactivity in the final development is too low, as illustrated in the left side and the center of FIG. 17, a part of the resist that was configuring the soluble region R2 may be adhered to the wafer W by development and remain to become a foreign substance R5. The foreign substance R5 is dissolved by increasing the development reactivity during the final development such that the foreign substance R5 does not remain on the wafer W at the end of the final development as illustrated on the right side of FIG. 17.

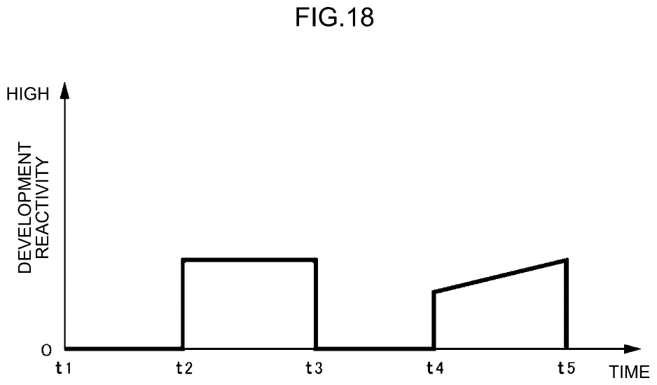

In the chart illustrated in FIG. 16, the development reactivity is constant from time t4A to time t5, but the development reactivity may be gradually increased from time t4A to time t5. Note that, as illustrated in the chart of FIG. 18, a case of gradually increasing the development reactivity from time t4 at which the final development is started to time t5 at which the final development is stopped also corresponds to a case of increasing the development reactivity during the final development.

Note that, after the final development is performed, processing of removing the foreign substance R5 may be performed such as supplying the developing solution from a nozzle to the wafer W to form a liquid film of the developing solution on the wafer W or exposing to plasma. The processing of removing the foreign substance R5 may be performed regardless of whether increase in development reactivity during the final development is performed. When the soluble region R2 remains, the soluble region R2 is removed by performing the processing of removing the foreign substance R5. Therefore, at the end of the final development, the soluble region R2 of the resist film R may not be completely removed and may remain on the wafer W as a thin layer. That is, the final development only needs to etch the soluble region R2 to a predetermined depth, and is not limited to etching until the lower layer film R4 is exposed.

### Repetition of Processing and Reactivity of Each PEB

It is described that, when the PEB and the development are performed twice, processing is performed such that the widening reactivity of the insoluble region R1 is different between the first PEB and the second PEB. When the PEB and the development are performed three or more times, as described with reference to FIGS. 13 to 15, for each PEB, for example, by setting the processing conditions such that the widening reactivity gradually increases as the number of PEB increases, the insoluble region R1 after development may have a shape that is approximate to a rectangle in side view. As a specific example, the temperature of the heating plate 64 may be increased as the number of PEB increases, and the widening reactivity may be gradually increased as described above.

Note that, when the PEB is performed three or more times, the processing conditions may be set such that the widening reactivity is the same for a plurality of consecutive PEBs. Specifically, when the PEB is performed three times and the widening reactivity is controlled by the temperature of the heating plate 64, the temperature of the heating plate 64 may be the same between the first PEB and the second PEB, or the temperature of the heating plate 64 may be the same between the second PEB and the third PEB.

### Processing by Mist

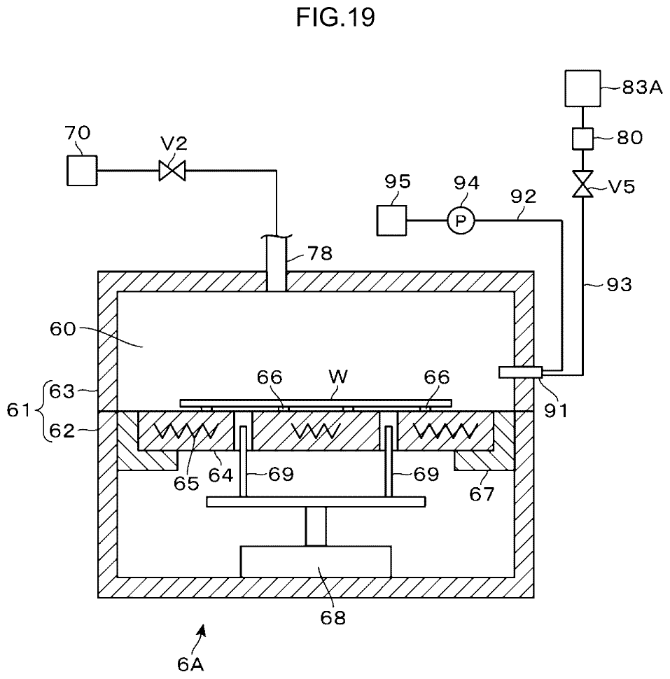

The developing fluid supplied to the wafer W is not limited to gas, and may be mist. FIG. 19 illustrates a longitudinal side view of a developing device 6A including a nozzle 91 that discharges mist to a processing space 60. The nozzle 91 is provided in the upper member 63 configuring the processing container 61, and downstream ends of flow routes 92 and 93 are connected to the nozzle 91. The flow route 92 is connected to a storage unit 95 storing the developing solution via a pump 94. The flow route 93 is connected to the N₂ gas supply mechanism 83A via a valve V5 and the flow adjustment unit 80 in this order toward the upstream side.

The developing solution is supplied from the storage unit 95 toward the nozzle 91 by the pump 94.

During the supply of the developing solution to the nozzle 91, the valve V5 is opened and the N₂ gas supplied from the N₂ gas supply mechanism 83A is supplied to the nozzle 91 at a predetermined flow. By mixing the developing solution and the N₂ gas in the nozzle 91, the developing solution is turned into mist and discharged to the processing space 60. By using the mist instead of the developing gas, the developing device 6A can process the wafer W similarly to the developing device 6.

In the developing device 6A, as described above, the operation of the pump 94 may be controlled to make the development reactivity different between each development. When increasing the development reactivity, a large amount of developing solution is supplied to the processing space 60 as mist by relatively increasing the amount of developing solution supplied to the nozzle 91 by the pump 94, and when reducing the development reactivity, a small amount of developing solution is supplied to the processing space 60 as mist by relatively reducing the amount of developing solution supplied to the nozzle 91 by the pump 94.

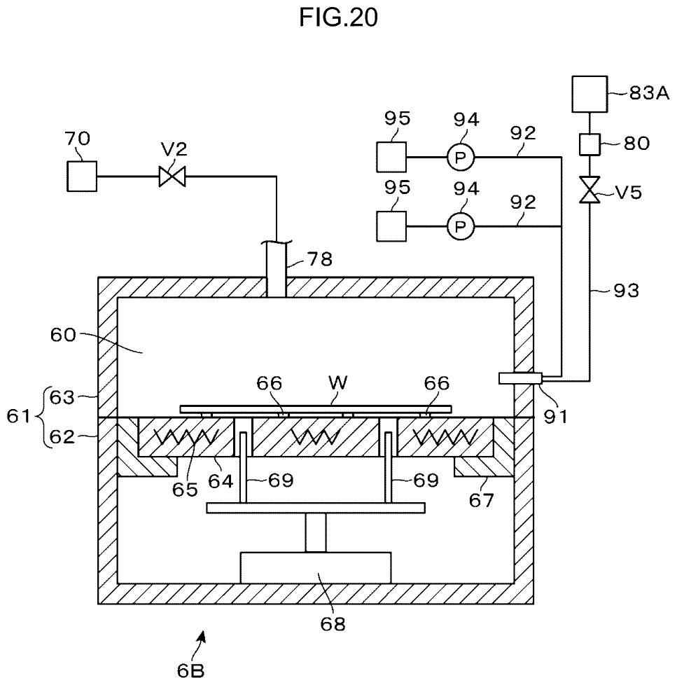

FIG. 20 is a longitudinal sectional side view of a developing device 6B as a modification of the developing device 6A. The developing device 6B is different from the developing device 6A in that a plurality of sets of the flow route 92, the pump 94, and the storage unit 95 for the developing solution are provided such that the developing solution is supplied from any of the storage units 95 to the nozzle 91 to generate the developing mist. The developing solution stored in each storage unit 95 is configured of a component that causes a developing reaction (developing component) and a solvent, and the concentration of the developing component in the developing solution is made different between each storage unit 95. When increasing the development reactivity, the developing solution is supplied to the nozzle 91 from the storage unit 95 containing the developing solution having a high concentration of the developing component, and when reducing the development reactivity, the developing solution is supplied to the nozzle 91 from the storage unit 95 containing the developing solution having a low concentration of the developing component, such that the development reactivity of each development can be made different.

In the developing device 6 of FIG. 6, the vaporization efficiency is different between the tanks 85 of the developing gas supply mechanisms 81A and 82A such that the concentration of the developing gas in the mixed gas supplied from each of the developing gas supply mechanisms 81A and 82A to the processing space 60 is different from each other. Instead of making the vaporization efficiency different between the developing gas supply mechanisms 81A and 82A as described above, the developing solutions each having different developing component concentrations may be used as in the example of FIG. 20. That is, the concentration of the developing component in the developing solution stored in the tank 85 may be made different between the developing gas supply mechanisms 81A and 82A such that the concentration of the developing gas in the gas supplied from each of the developing gas supply mechanisms 81A and 82A to the processing space 60, that is, the concentration of the vaporized developing components may be made different from each other, and the development reactivity is made different for each development.

### Second Embodiment

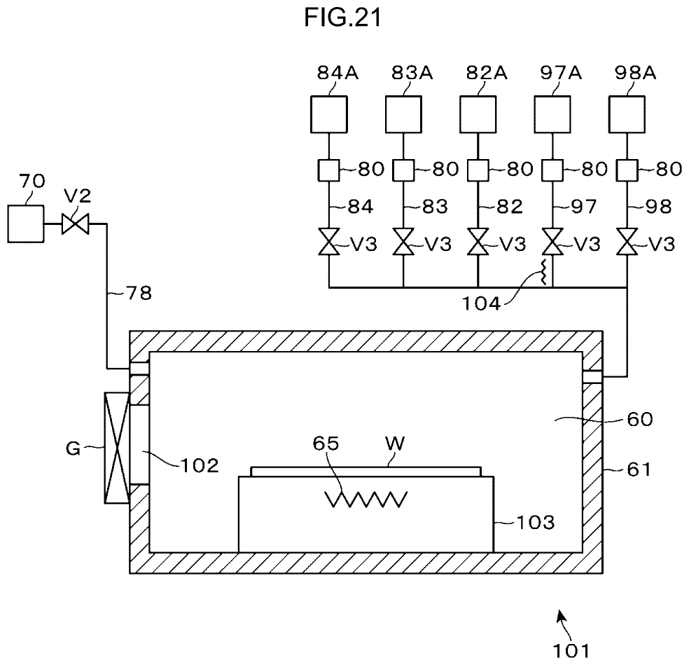

FIG. 21 is a longitudinal sectional side view of a developing device 101 according to a second embodiment. To describe differences from the developing device 6, in the developing device 101, the processing container 61 is not vertically divided, and a transfer port 102 on the side wall is opened and closed by a gate valve G such that the wafer W is transferred by the wafer transfer device 33. In the drawing, reference numeral 103 denotes a stage configuring a placement part on which the wafer W is placed, and similarly to the heating plate 64 of the first embodiment, the wafer W placed on the stage is subjected to heat processing by the embedded heater 65. The developing device 101 is provided with the pin 69 that is moved upward and downward by the vertical movement mechanism 68 similarly to the heating plate 64 to transfer the wafer W between the wafer transfer device 33 and the stage 103, but the pin 69 is not illustrated.

Similarly to the first embodiment, the gas supply routes 82 to 84 are connected to the processing container 61, and the developing gas, the N₂ gas, and the water vapor can be supplied from each of the gas supply routes 82 to 84 to the processing space 60. Gas supply routes 97 and 98 are connected to the processing container 61. In each of the gas supply routes 97 and 98, similarly to the other gas supply routes 82 to 84, the valve V3 and the flow adjustment unit 80 are sequentially interposed. A developing gas supply mechanism 97A and a dilution gas supply mechanism 98A are connected to each of upstream ends of the gas supply routes 97 and 98. HBr gas that is strong acid is supplied as the developing gas from the developing gas supply mechanism 97A. A heater 104 that heats the developing gas flowing through the gas supply route 97 and adjusts the temperature of the developing gas is provided. Note that, in the example, each gas is supplied to the processing space 60 without passing through the shower head 75.

For example, BCl₃ gas is supplied as dilution gas from the dilution gas supply mechanism 98A. When the developing gas is supplied from the developing gas supply mechanism 97A toward the processing space 60, the dilution gas is also supplied from the dilution gas supply mechanism 98A toward the processing space 60. Note that, as in the first embodiment, the developing gas supply mechanism 82A supplies the acetic acid gas that is weak acid as the developing gas toward the processing space 60. Therefore, the developing gas supply mechanisms 97A and 82A each supply the developing gas containing HBr as a first compound and the developing gas containing the acetic acid as a second compound, and the first compound is stronger acid than the second compound. That is, the first compound has a larger acid dissociation constant (Ka) than the second compound.

### Regarding Vacuum Processing

In the second embodiment, the PEB and the development are performed while the processing space 60 is set to a vacuum atmosphere of a preset pressure lower than the atmospheric pressure, specifically, for example, a pressure equal to or less than 103 Pa by exhausting the inside of the processing container 61 by the exhaust mechanism 70.

The reason for the vacuum processing is described. It is considered that, during the period from the formation of the resist film R on the wafer W to the PEB, a part of the raw material compound M1 in the soluble region R2 is decomposed and precipitated as an impurity to the lower part side of the soluble region R2, and when the processing space 60 becomes a vacuum atmosphere, the impurity is removed from the insoluble region R1. A part of the raw material compound M1 in the soluble region R2 moves into a space formed by removing the impurity, for example, by its own weight. That is, it is considered that a density of the raw material compound M1 on the lower part side of the soluble region R2 increases, but a density of the raw material compound M1 on the upper part side of the soluble region R2 decreases.

As described above, the reaction product M2 in the insoluble region R1 reacts with the raw material compound M1 in the soluble region R2, thereby widening the lower part side of the insoluble region R1 during the PEB. Therefore, each PEB is preferably performed in the vacuum atmosphere since a distribution of the raw material compound M1 in the soluble region R2 is adjusted such that the lower part side of the insoluble region R1 is preferably widened. Note that, in the example, all PEBs are performed in the vacuum atmosphere, but the widening may be performed by performing only a part of PEBs in the vacuum atmosphere. To enhance the widening property of the insoluble region R1, the vacuum atmosphere is required to be formed only during the PEB, but in the example, to prevent a decrease in the throughput, development is also performed in the vacuum atmosphere.

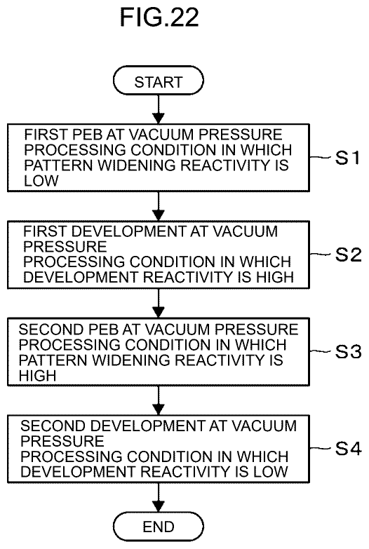

Hereinafter, a processing example of the wafer W using the developing device 101 is described focusing on differences from the processing of FIGS. 6 to 10 by the developing device 6 by taking a case in which the PEB and the development are each performed twice as an example. Note that, in the processing example, the developing gas is supplied only from the developing gas supply mechanism 97A of the developing gas supply mechanism 82A and the developing gas supply mechanism 97A to perform development. In the description, the flowchart in FIG. 22 is referred to as appropriate.

First, the processing space 60 is evacuated to form the vacuum atmosphere having the predetermined pressure. Then, for example, the wafer W is transferred to the processing space 60 by the wafer transfer device 33 via a transfer region in the vacuum atmosphere outside the processing container 61. The transfer port 102 of the processing container 61 is closed, and the N₂ gas is supplied to the processing space 60. Then, the wafer W is placed on the stage 103 heated to B1° C., and the first PEB is performed in the N₂ gas atmosphere (step S1).

Next, the supply of the N₂ gas to the processing space 60 is stopped, and the developing gas and the dilution gas are supplied from each of the developing gas supply mechanism 97A and the dilution gas supply mechanism 98A to the processing space 60, such that the mixed gas in which the developing gas and the dilution gas are mixed is supplied to the processing space 60 and the first development is performed (step S2). Thereafter, the supply of the developing gas and the dilution gas to the processing space 60 is stopped, the first development is stopped, the N₂ gas is supplied, and the second PEB is started in the N₂ gas atmosphere (step S3).

Subsequently, the mixed gas described above is supplied again to the processing space 60, and the second development is performed (step S4). Next, the supply of the developing gas and the dilution gas to the processing space 60 is stopped, the second development is stopped, the N₂ gas is supplied, the mixed gas is purged from the processing space 60, and then the wafer W is carried out from the processing space 60. Since the processing space 60 is maintained at the vacuum pressure described above from carrying-in to carrying-out the wafer W, each PEB and each development are performed at the vacuum pressure.

In the processing of the developing device 101 described above, for the first development and the second development, the processing conditions are set such that the development reactivity in the first development is higher than that in the second development as in the first embodiment. That is, one or a plurality of the parameters such as the temperature of the wafer W, the temperature of the developing gas, the flow of the developing gas, and the concentration of the developing gas in the mixed gas supplied to the processing space 60 have different values between the first development and the second development such that the development reactivity is higher in the first development than in the second development. Note that the change of the temperature of the developing gas and the change of the flow of the developing gas supplied to the processing space 60 may be performed by changing each of the output of the heater 104 and the operation of the flow adjustment unit 80 of the gas supply route 98. For the first PEB and the second PEB, similarly to the first embodiment, the processing conditions may be set such that the widening reactivity is higher in the second PEB than in the first PEB.

Note that HBr used as the developing gas in the example has relatively high reactivity with the resist film R. To prevent excessive etching of the insoluble region R1, for example, the temperature of the stage 103 in each development is set to be lower than the temperature of the stage 103 in each PEB. The temperature of the stage 103 in each development is, for example, 10° C. to 40° C., that is a normal temperature or a temperature close to the normal temperature.

The discharge port 71 may be provided in the stage 103 and the back-surface-side purge gas may be supplied to the back surface of the wafer W during development as in the first embodiment. Although the back-surface-side purge gas is described as the inert gas in the first and second embodiments, the back-surface-side purge gas is not limited to the inert gas, and for example, gas containing the developing gas may be used. The developing gas may be any developing gas described above, and the dissolved product of the resist film R attached to the back surface side of the wafer W is removed by the developing gas. In each development, the developing gas may be supplied as the back-surface-side purge gas in a part of the developments including the final development, and the gas not containing the developing gas may be supplied as the back-surface-side purge gas in other developments.

Note that, in addition to the supply of the back-surface-side purge gas, each technique described in the first embodiment can be applied to the second embodiment. Therefore, in the second embodiment, for example, the number of times of repetition of the PEB and the development is also freely selected, and the relationship of the level of the development reactivity between each development when the development is repeated, the change of the development reactivity during the same development, and the relationship of the level of the widening reactivity between each PEB can also be controlled, similarly to the example described in the first embodiment.

### Another Example of Operation of Developing Device of Second Embodiment

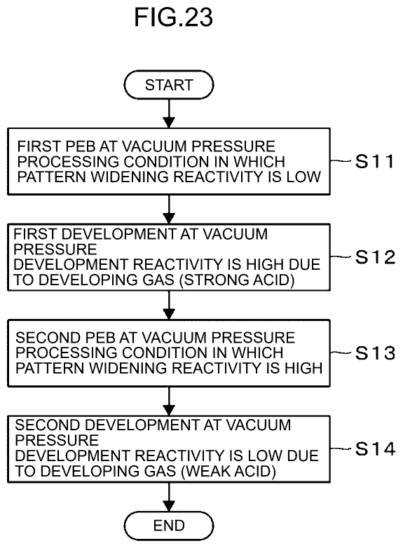

Next, a processing example of the developing device 101 using the developing gas supplied from the developing gas supply mechanism 82A and the developing gas supply mechanism 97A is described with reference to the flowchart in FIG. 23, focusing on differences from the processing example described with reference to FIG. 22. First, after the wafer W transferred to the processing space 60 at the vacuum pressure is placed on the stage 103 at B1° C. and heated at B1° C. to perform the first PEB (step S11), gas is supplied from each of the developing gas supply mechanism 97A and the dilution gas supply mechanism 98A and the mixed gas of the supplied gases is supplied to the processing space 60 (step S12). That is, the gas containing HBr that is strong acid is supplied to the wafer W as the developing gas, and the first development is performed. To prevent excessive reaction occurring due to HBr, the temperature of the stage 103 is set to a temperature within the range described above, and set to B5° C. lower than B1° C.

Thereafter, the supply of the mixed gas described above to the processing space 60 is stopped, the second PEB is performed on the wafer W, and the temperature of the stage 103 is set to B3° C. higher than B1° C. and B5° C. to increase the widening reactivity (step S13). Then, the mixed gas is supplied from the developing gas supply mechanism 82A. That is, the gas containing the acetic acid that is weak acid is supplied to the wafer W as the developing gas, and the second development is performed (step S14). To prevent liquefaction of the developing gas that is the acetic acid, the temperature of the stage 103 in step S14 is set to the temperature (B2° C.) during the supply of the developing gas described in the first embodiment, and B2° C. is higher than B5° C. that is the temperature of the stage 103 in step S12.

After the second development is completed, the processing space 60 is purged with the N₂ gas, and the wafer W is carried out from the processing space 60. In the above processing, as illustrated in FIG. 10, the development reactivity is higher in the first development than in the second development due to the difference in the type of gas to be used. Note that the processing conditions other than the type of gas to be used may be the same or different in the first development and the second development.

HBr used as the developing gas in the first development has a relatively small molecular weight, and thus easily permeates the resist film R. When HBr is released from the resist film R of the wafer W carried out to the outside of the processing container 61, there is a possibility that metals configuring devices and systems near the wafer W are corroded. To prevent such corrosion, in the processing of steps S11 to S14, the acetic acid gas is used as the developing gas for the second development as gas other than HBr.

The reason of changing the type of the developing gas as described above is that, when the temperature of the heating plate 64 in the second PEB in step S13 is higher than that in the first development in step S12, HBr that permeated the resist film R in the first development volatilizes and is removed. Thereafter, since the HBr gas is not supplied as the developing gas in the second development in step S14, permeation of HBr into the resist film R does not newly occur. Here, since the temperature of the heating plate 64 in the second development is higher than the temperature of the heating plate 64 in the first development, the volatilization of HBr further proceeds in the resist film R.

Therefore, even when the wafer W carried out from the developing device 101 is exposed to a temperature environment higher than the temperature in the first development, the amount of HBr released from the resist film R is 0 or very small. Note that, since the acetic acid has a relatively large molecular weight, permeation of the acetic acid into the resist film R hardly occurs. Even when the wafer W is carried out from the processing space 60 of the developing device 101 while the acetic acid remains on the resist film R due to the permeation and the acetic acid is released from the resist film R after carrying out, since the acetic acid is weak acid, corrosiveness to metal is low. That is, according to the methods in steps S11 to S14, corrosion problem is preferably prevented from occurring. Note that, when the PEB and the development are repeatedly performed three or more times, the HBr gas may be used at each development from the first development to an m-th (m is an integer) development, and the acetic acid gas may be used at each development from an (m+1)-th development to the final development.

In each embodiment, it is described that the PEB and the development are performed in the same processing container 61, but the PEB and the development may be performed in different processing containers 61. The PEB and the development may be performed in different processing containers 61. Different PEBs may be performed in different processing containers 61, or different developments may be performed in different processing containers 61. When processing is performed in the wafer processing system 1 described above, the PEB may be performed by the heat processing apparatus, the development may be performed by the developing device, and the wafer W may be transferred between the heat processing apparatus and the developing device by the wafer transfer devices 33. Note that, gas to be used in the PEB is gas having a low influence on the surroundings, such as the N₂ gas. Therefore, the heat processing apparatus that performs only the PEB without performing the development may not include the processing container 61. As described above, the substrate processing apparatus that performs the PEB and the development may be configured as an apparatus that includes one processing container and performs each processing in the processing container, as in the developing device 6, or may be configured to include an apparatus provided with a placement part on which each wafer W is placed and a transfer device (transfer mechanism) that transfers the wafer W between the apparatuses.

In the second embodiment, it is described that each processing is performed at the vacuum pressure, but the processing is not limited to being performed at the vacuum pressure as described above, and any of the PEB and the development, any of the PEBs, or any of the developments may be performed at the atmospheric pressure. Therefore, for example, the first PEB may be performed at the atmospheric pressure, and processing after the first development may be performed at the vacuum pressure. Note that, in the first embodiment, any or all of the PEBs and the developments may be performed in the vacuum atmosphere. Noted that the PEB is not limited to being performed on the heating plate 64 and may be performed by irradiating the wafer W with light by an LED or the like.

The PEB may not be performed a plurality of times. In the processing container 61, after the PEB is performed, the developing gas is supplied, and the processing conditions may be changed during the supply of the developing gas to decrease the development reactivity. The first development is performed before the processing conditions are changed, and the second development is performed after the processing conditions are changed. The configuration of the substrate processing apparatus illustrated as the developing device can be appropriately modified. A flow route configuration for introducing each gas into the processing space 60, the position of the heater for heating the gas in the flow route, and the like can be appropriately changed.

In each embodiment, the substrate to be processed is not limited to the wafer, and may be, for example, a substrate for manufacturing a flat panel display or a mask substrate for manufacturing an exposure mask. Therefore, a rectangular substrate may be processed. The embodiments disclosed herein should be considered to be illustrative in all respects and not restrictive. The embodiments described above may be omitted, replaced, modified, and combined in various forms without departing from the scope and spirit of the appended claims.

In the present disclosure, a resist pattern having a good shape can be obtained by a developing fluid that is gas or mist.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A substrate processing method of forming a pattern by supplying a developing fluid that is gas or mist to a substrate and developing a resist film formed on the substrate and containing metal, the substrate processing method comprising:
a first heat processing step of performing heat processing on the substrate after the resist film is exposed along the pattern;
a first developing step of supplying the developing fluid to the substrate on which the first heat processing step is performed and removing a part of the resist film in a depth direction; and
a second developing step of supplying the developing fluid to the substrate on which the first developing step is performed for forming the pattern and removing a region from which the resist film is removed by the first developing step in the depth direction to a development completion position.

2. The substrate processing method according to claim 1, further comprising a second heat processing step of performing heat processing on the substrate after the first developing step is performed and before the second developing step is performed.

3. The substrate processing method according to claim 2, wherein the first developing step is a step performed under a processing condition in which development reactivity with respect to the resist film is higher than in the second developing step.

4. The substrate processing method according to claim 3, wherein the processing condition in which the development reactivity is high is a processing condition defined by at least one of (1) to (3):
(1) a concentration of the developing fluid in gas supplied into a processing container that stores the substrate is higher in the first developing step than in the second developing step;
(2) an amount of the developing fluid supplied into the processing container is larger in the first developing step than in the second developing step; and
(3) the first developing step includes a step of heating the substrate during the supply of the developing fluid, and a temperature of the substrate to which the developing fluid is supplied in the first developing step is higher than a temperature of the substrate to which the developing fluid is supplied in the second developing step.

5. The substrate processing method according to claim 1, wherein the second heat processing step is performed under a processing condition in which reactivity of making the resist film insoluble in the developing fluid is higher than in the first heat processing step.

6. The substrate processing method according to claim 5, wherein the processing condition in which the reactivity of making the resist film insoluble in the developing fluid is higher is a processing condition defined by at least any one of (a) to (d):
(a) the first heat processing step and the second heat processing step include a step of placing the substrate on a placement part, and
a temperature of the placement part in the second heat processing step is higher than a temperature of a heating plate in the first heat processing step;
(b) the first heat processing step and the second heat processing step include a step of supplying heating gas to a lower surface of the substrate, and
a temperature of the heating gas in the second heat processing step is higher than a temperature of the heating gas in the first heat processing step;
(c) the first heat processing step and the second heat processing step include a step of supplying inert gas to the lower surface of the substrate, and
a flow of the inert gas supplied to the substrate in the second heat processing step is larger than a flow of the inert gas supplied to the substrate in the first heat processing step; and
(d) the first heat processing step and the second heat processing step include a step of placing the substrate on the placement part provided in a processing container that stores the substrate and supplying the inert gas into the processing container while heating, and
a concentration of the inert gas in the processing container in the first heat processing step is larger than a concentration of the inert gas in the processing container in the second heat processing step.

7. The substrate processing method according to claim 1, further comprising a step of changing a processing condition during the second developing step such that the development reactivity with respect to the resist film is increased.

8. The substrate processing method according to claim 1, wherein
the developing fluid is supplied to the substrate a plurality of times, and
the first developing step is a step of supplying the developing fluid at first, the second developing step is a step of supplying the developing fluid finally, and the substrate processing method includes a step of gradually reducing the development reactivity of the developing fluid with respect to the resist film as the number of times of supply of the developing fluid increases.

9. The substrate processing method according to claim 2, wherein the first heat processing step or the second heat processing step is a step of performing heat processing on the substrate in a processing container in which a vacuum atmosphere is formed.

10. The substrate processing method according to claim 1, wherein the first developing step includes a step of supplying the developing fluid containing a first compound to the substrate, the second developing step includes a step of supplying the developing fluid containing a second compound to the substrate, and the first compound is a compound having stronger acidity than the second compound.

11. A substrate processing apparatus configured to form a pattern by supplying a developing fluid that is gas or mist to a substrate and developing a resist film formed on the substrate and containing metal, the substrate processing apparatus comprising:
a heat processing unit configured to perform heat processing on the substrate after the resist film is exposed along the pattern;
a developing fluid supply unit configured to supply the developing fluid to the substrate; and
a controller configured to output a control signal to perform
a first developing step of supplying the developing fluid to the substrate on which the heat processing is performed by the heat processing unit and removing a part of the resist film in a depth direction, and
a second developing step of supplying the developing fluid to the substrate on which the first developing step is performed for forming the pattern and removing a region from which the resist film is removed in the first developing step in the depth direction to a development completion position.

12. A storage medium that stores a computer program used in a substrate processing apparatus, wherein the computer program includes a step group for executing the substrate processing method according to claim 1.
